(19) United States
(12) Patent Application Publication
(10) Pub. No.: US 2007/0285010 A1
(43) Pub. Date: Dec. 13, 2007

(54) Organic light emitting device

(76) Inventors: Tae-Woo Lee, Yongin-si (KR); Jong-Jin Park, Yongin-si (KR); Mu-Hyun Kim, Suwon-si (KR); Seung-Wook Chang, Suwon-si (KR)

Correspondence Address: Robert E. Bushnell, Suite 300, 1522 K Street, N.W., Washington, DC, 20005, US

(21) Appl. No.: 11/785,100

(22) Filed: Apr. 13, 2007

(30) Foreign Application Priority Data
Jun. 7, 2006 (KR) 10-2006-0051085

(51) Int. Cl. H05B 33/00

(52) U.S. Cl. 313/504

(57) ABSTRACT

Provided are an organic light emitting device (OLED) comprising: a first electrode; a second electrode; a hole injection layer (HIL), a hole transporting layer (HTL), and an emitting layer sequentially formed between the first electrode and the second electrode, wherein the work function, the IP or the absolute value of the highest occupied molecular orbital (HOMO) level of the HIL is greater than or equal to the absolute value of HOMO level of the HTL. In the OLED, the energy relationships between organic layers are controlled to facilitate hole injection and optimize the charge balance. Thus the efficiency of the OLED improves and the lifetime of the OLED increases.

### CLAIM OR PRIORITY

This application claims the benefit of Korean Patent Application No. 10-2006-0051085, filed on Jun. 7, 2006 in the Korean Intellectual Property Office, the disclosure of which is incorporated herein in its entirety by reference.

### BACKGROUND OF THE INVENTION

1. Field of the Invention

The present invention relates to an organic light emitting device (OLED), and more particularly, to an OLED in which energy relationships of layers forming the OLED are controlled to facilitate hole injection and optimize the charge balance to obtain an OLED having improved efficiency and increased lifetime.

2. Description of the Related Art

An organic light emitting device is a self-emissive display device using the principle that when current is applied to a fluorescent or phosphorescent organic compound thin layer (hereinafter referred to as ‘organic layer’), electrons and holes combine in the organic layer and thus light is generated. An organic light emitting device can be made light, is easy to manufacture because of simple elements thereof, and can provide a wide viewing angle and a high quality image. Also, a light emitting device can realize perfect moving images and high color purity and can be operated at low power and low voltage, and thus is appropriate for mobile electronic devices.

Organic light emitting devices can be classified into small molecule organic light emitting devices and polymer light emitting devices, depending on the material and the process forming the organic layer.

Small molecule organic light emitting devices can be manufactured using a vacuum deposition method. In small molecule organic light emitting devices the light emitting material can be easily purified, high purity can be easily obtained, and color pixels can be easily realized. Despite the advantages of small molecule organic light emitting devices, improvements are still required for practical application, for example, improvement of quantum efficiency and color purity and preventing the thin layers from being crystallized.

Meanwhile, since the Cambridge group reported in 1990 that light is emitted when power is applied to a poly(1,4-phenylenvinylene) (PPV), which is a π-conjugated polymer, research into a light emitting device using a polymer has been vigorously conducted. A π-conjugated polymer has a chemical structure in which a single bond (or σ-bond) and a double bond (or π-bond) are alternated, and thus has a π-electron that can move relatively freely according to the bonding chain without being localized. Due to the semiconductor property of the π-conjugated polymer, when the π-conjugated polymer is applied to an emitting layer of an electroluminescent device, light of the entire region corresponding to a HOMO-LUMO band-gap can be easily obtained using a molecular design. Also, when the π-conjugated polymer is used, thin films can be formed in a simple way using a spin-coating or printing method, which simplifies the manufacturing process of the device and reduces costs, and since the π-conjugated polymer has a high glass transition temperature, a thin film having excellent mechanical properties can be provided. Accordingly, an EL device using a polymer is expected to have greater commercial competency than a small molecular light emitting device in the long run.

Such a polymer light emitting device includes not only a single emitting layer as an organic layer for improving efficiency and reducing driving voltage, but has a multi-layer structure including a hole injection layer (HIL), an emitting layer, an electron injection layer, etc. using conducting polymers.

In particular, a poly(3,4-ethylenedioxythiophene))-poly(4-styrene-sulfonate (PEDOT-PSS) solution which is manufactured by Bayer AG and sold under the name Baytron-P is widely used to be spin-coated on an indium tin oxide (ITO) electrode for forming an HIL when an light emitting device is manufactured. The hole injection material PEDOT-PSS has a structure as represented below.

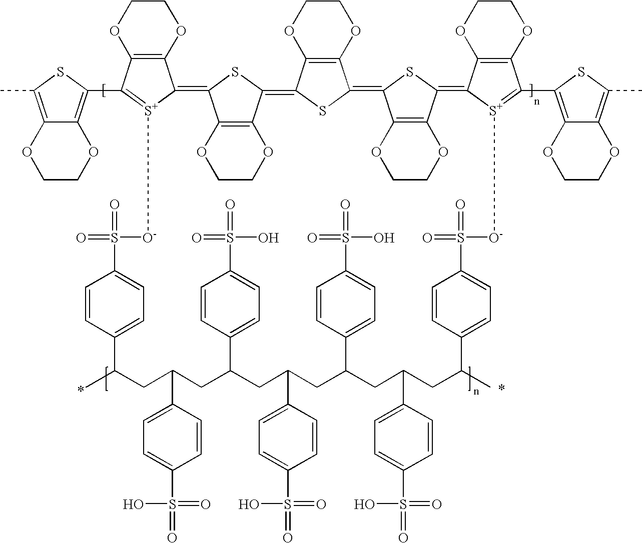

However, the PEDOT/PSS composition has a work function from 5.0 to 5.2 eV, and thus is not advantageous for hole injection because the energy barrier between a polyfluorene derivative having generally a highest occupied molecular orbital (HOMO) value of greater than 5.5 eV and the PEDOT/PSS composition is greater than 0.3 eV, which makes hole injection difficult. Thus, due to the energy gap between the ITO which is used mainly as an anode and the emitting layer, an electron injection layer and a hole transporting layer (HTL) are always required for recently optimized OLEDs. In addition, the OLEDs are designed such that the absolute values of the work function, the ionization energy, or the HOMO of the HIL and the HTL increase stepwise in a direction from the ITO to the emitting layer. Conventionally, it is well-known in the art that when a HIL formed on the ITO has a greater work function, ionization energy, or absolute value of HOMO than a HOMO value of the HTL and the emitting layer, the work function is 4.7 to 4.9 eV, and thus a great energy barrier is present between the ITO and the HIL, and thus hole injection becomes difficult.

### SUMMARY OF THE INVENTION

The present invention provides an improved organic light emitting device (OLED).

The present invention provides an organic light emitting device (OLED) having improved efficiency and increased lifetime by facilitating hole injection and optimizing charge balance.

According to an aspect of the present invention, there is provided an OLED comprising: a first electrode; a second electrode; an emitting layer between the first electrode and the second electrode; a hole injection layer between the first electrode and the emitting layer; a hole transporting layer between the hole injection layer and the emitting layer, the absolute value of the work function, the IP or the highest occupied molecular orbital (HOMO) level of the hole injection layer is greater than or equal to the absolute value of the HOMO level of the hole transporting layer.

The HIL may be provided through a solution process.

A hole blocking layer and/or an electron transporting layer (ETL) may be further included between the HIL and the second electrode.

The difference of the absolute values of the work function, the IP, and the HOMO level between the HIL and the HTL may be 0.2 eV or greater.

The electron mobility of the ETL may be from 1×10⁻⁵ cm²/Vs to 1×10⁻² cm²/Vs in an electric field of 800 to 1,000 (V/cm)^{1/2}.

The HIL may include a conducting polymer or a conducting polymer composition including fluorinated or perfluorinated ionomer.

The conducting polymer may be one selected from the group consisting of polythiophene, poly(3,4-ethylene dioxythiophene) (PEDOT), polyaniline, polypyrrole, polyacetylene, derivatives thereof, and a self-doped conducting polymer.

The self-doped conducting polymer may have a composition represented by Formula 1 below having a degree of polymerization of 10 to 10,000,000:

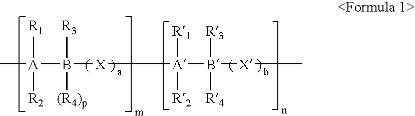

where 0<m<10,000,000, 0<n<10,000,000, 0≦a≦20, 0≦b≦20, and 2≦p≦10,000,000;

at least one of R₁, R₂, R₃, R′₁, R′₂, R′₃, and R′₄ includes an ionic group, and A, B, A′, and B′ are each independently selected from C, Si, Ge, Sn, or Pb;

R₁, R₂, R₃, R′₁, R′₂, R′₃, and R′₄, are each independently selected from the group consisting of a hydrogen, halogen, a nitro group, a substituted or unsubstituted amino group, a cyano group, a substituted or unsubstituted C₁-C₃₀ alkyl group, a substituted or unsubstituted C₁-C₃₀ alkoxy group, a substituted or unsubstituted C₆-C₃₀ aryl group, a substituted or unsubstituted C₆-C₃₀ arylalkyl group, a substituted or unsubstituted C₆-C₃₀ aryloxy group, a substituted or unsubstituted C₂-C₃₀ heteroaryl group, a substituted or unsubstituted C₂-C₃₀ heteroarylalkyl group, a substituted or unsubstituted C₂-C₃₀ heteroaryloxy group, a substituted or unsubstituted C₅-C₃₀ cycloalkyl group, a substituted or unsubstituted C₅-C₃₀ heterocycloalkyl group, a substituted or unsubstituted C₁-C₃₀ alkylester group, and a substituted or unsubstituted C₆-C₃₀ arylester group;

R₄ is formed of a conjugated conducting polymer chain; and

X and X′ are each independently selected from the group consisting of a simple bond, O, S, a substituted or unsubstituted C₁-C₃₀ alkylene group, a substituted or unsubstituted C₁-C₃₀ heteroalkylene group, a substituted or unsubstituted C₆-C₃₀ arylene group, a substituted or unsubstituted C₆-C₃₀ arylalkylene group, a substituted or unsubstituted C₂-C₃₀ heteroarylene group, a substituted or unsubstituted C₂-C₃₀ heteroarylakylene group, a substituted or unsubstituted C₅-C₂₀ cycloalkylene group, a substituted or unsubstituted C₅-C₃₀ heterocycloalkylene group, and a substituted or unsubstituted C₆-C₃₀ arylester group.

The fluorinated ionomer included in the HIL may include a polymer having at least one of the repeating units represented by Formulas 2 through 12:

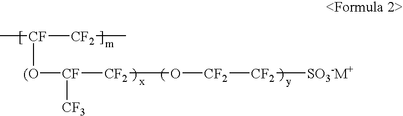

where m is an integer from 1 to 10,000,000, and x and y are each a number from 0 to 10, M⁺ is Na⁺, K⁺, Li⁺, H⁺, CH₃(CH₂)ₙNH₃⁺ (n is an integer from 0 to 50), NH₄⁺, NH₂⁺, NHSO₂CF₃⁺, CHO⁺, C₂H₅OH⁺, and CH₃OH⁺, and RCHO⁺ where R is an alkyl group, that is, CH₃(CH₂)ₙ⁻ where n is an integer from 0 to 50.

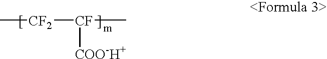

where m is an integer from 1 to 10,000,000.

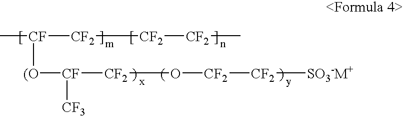

where 0<m≦10,000,000, 0≦n<10,000,000, and x and y are each a number from 0 to 20, M⁺ is Na⁺, K⁺, Li⁺, H⁺, CH₃(CH₂)ₙNH₃⁺ (n is an integer from 0 to 50), NH₄⁺, NH₂⁺, NHSO₂CF₃⁺, CHO⁺, C₂H₅OH⁺, CH₃OH⁺, and RCHO⁺ where R is an alkyl group, that is, CH₃(CH₂)ₙ⁻ where n is an integer from 0 to 50.

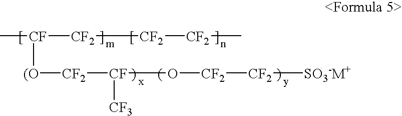

where 0<m≦10,000,000, 0≦n<10,000,000, and x and y are each 0 to 20, M⁺ is Na⁺, K⁺, Li⁺, H⁺, CH₃(CH₂)ₙNH₃⁺ (n is an integer from 0 to 50), NH₄⁺, NH₂⁺, NHSO₂CF₃⁺, CHO⁺, C₂H₅OH⁺, CH₃OH⁺, and RCHO⁺ where R is an alkyl group, that is, CH₃(CH₂)ₙ⁻ where n is an integer from 0 to 50.

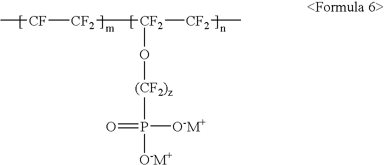

where 0<m≦10,000,000, 0≦n<10,000,000, and x and y are each a number from 0 to 20, M⁺ is Na⁺, K⁺, Li⁺, H⁺, CH₃(CH₂)ₙNH₃⁺ (n is an integer from 0 to 50), NH₄⁺, NH₂⁺, NHSO₂CF₃⁺, CHO⁺, C₂H₅OH⁺, CH₃OH⁺, and RCHO⁺ where R is an alkyl group, that is, CH₃(CH₂)ₙ⁻ where n is an integer from 0 to 50.

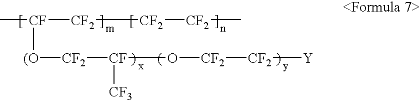

where 0<m≦10,000,000, 0≦n<10,000,000, and x and y are each a number from 0 to 20, M⁺ is Na⁺, K⁺, Li⁺, H⁺, CH₃(CH₂)ₙNH₃⁺ (n is an integer from 0 to 50), NH₄⁺, NH₂⁺, NHSO₂CF₃⁺, CHO⁺, C₂H₅OH⁺, CH₃OH⁺, and RCHO⁺ where R is an alkyl group, that is, CH₃(CH₂)ₙ⁻ where n is an integer from 0 to 50.

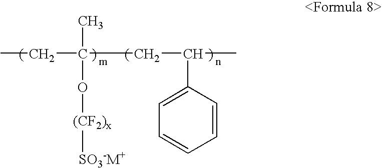

where 0<m≦10,000,000, 0≦n<10,000,000, and x and y are each a number from 0 to 20, M⁺ is Na⁺, K⁺, Li⁺, H⁺, CH₃(CH₂)ₙNH₃⁺ (n is an integer from 0 to 50), NH₄⁺, NH₂⁺, NHSO₂CF₃⁺, CHO⁺, C₂H₅OH⁺, CH₃OH⁺, and RCHO⁺ where R is an alkyl group, that is, CH₃(CH₂)ₙ⁻ where n is an integer from 0 to 50.

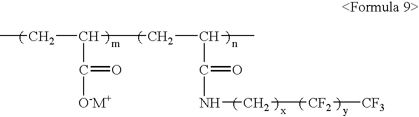

where 0<m≦10,000,000, 0≦n<10,000,000, and x and y are each a number from 0 to 20, M⁺ is Na⁺, K⁺, Li⁺, H⁺, CH₃(CH₂)ₙNH₃⁺ (n is an integer from 0 to 50), NH₄⁺, NH₂⁺, NHSO₂CF₃⁺, CHO⁺, C₂H₅OH⁺, CH₃OH⁺, and RCHO⁺ where R is an alkyl group, that is, CH₃(CH₂)ₙ⁻ where n is an integer from 0 to 50.

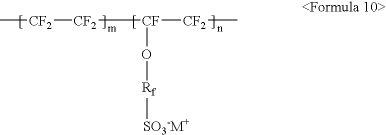

where 0≦m<10,000,000, 0<n≦10,000,000, R_{f}═—(CF₂)_{z}— (z is an integer from 1 to 50, except 2), —(CF₂CF₂O)_{z}CF₂CF₂— (z is an integer from 1 to 50), —(CF₂CF₂CF₂O)_{z}CF₂CF₂— (z is an integer from 1 to 50), M⁺ is Na⁺, K⁺, Li⁺, H⁺, CH₃(CH₂)ₙNH₃⁺ (n is an integer from 0 to 50), NH₄⁺, NH₂⁺, NHSO₂CF₃⁺, CHO⁺, C₂H₅OH⁺, CH₃OH⁺, and RCHO⁺ where R is an alkyl group, that is, CH₃(CH₂)ₙ⁻ where n is an integer from 0 to 50.

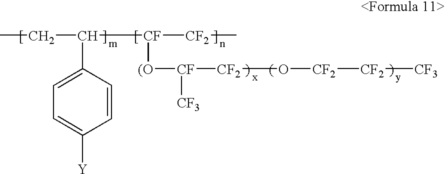

where m and n 0≦m<10,000,000, 0<n≦10,000,000, x and y are each a number from 0 to 20, Y is one selected from the group consisting of —SO₃⁻M⁺, —COO⁻M⁺, —SO₃⁻NHSO₂CF3⁺, and —PO₃²⁻(M⁺)₂, M⁺ is Na⁺, K⁺, Li⁺, H⁺, CH₃(CH₂)ₙNH₃⁺ (n is an integer from 0 to 50), NH₄⁺, NH₂⁺, NHSO₂CF₃⁺, CHO⁺, C₂H₅OH⁺, CH₃OH⁺, and RCHO⁺ where R is an alkyl group, that is, CH₃(CH₂)ₙ⁻ where n is an integer from 0 to 50.

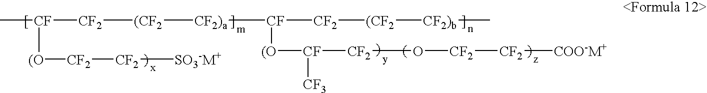

where 0≦m<10,000,000, 0<n≦10,000,000, M⁺ is Na⁺, K⁺, Li⁺, H⁺, CH₃(CH₂)ₙNH₃⁺ (n is an integer from 0 to 50), NH₄⁺, NH₂⁺, NHSO₂CF₃⁺, CHO⁺, C₂H₅OH⁺, CH₃OH⁺, and RCHO⁺ where R is a C₁-C₅₁ alkyl group, that is, CH₃(CH₂)ₙ⁻ where n is an integer from 0 to 50.

Accordingly, the efficiency and the life time of the OLED of the present invention are improved by controlling the energy relationship between the organic layers and facilitating hole injection and optimizing charge balance.

### BRIEF DESCRIPTION OF THE DRAWINGS

A more complete appreciation of the present invention, and many of the above and other features and advantages of the present invention, will be readily apparent as the same becomes better understood by reference to the following detailed description when considered in conjunction with the accompanying drawings in which like reference symbols indicate the same or similar components, wherein:

FIGS. 1A through 1D illustrate structures of organic light emitting devices (OLED) according to embodiments of the present invention.

FIG. 2A is a diagram of an energy band illustrating the difference between a highest occupied molecular orbital (HOMO) level and a lowest unoccupied molecular orbital (LUMO) level of layers of a conventional OLED;

FIG. 2B is a diagram of an energy band illustrating the difference between a HOMO level and a LUMO level of layers of an OLED according to an embodiment of the present invention;

FIG. 3A is a diagram of an energy band illustrating the difference between a HOMO level and a LUMO level of layers of another conventional OLED; and

FIG. 3B is a diagram of an energy band illustrating the difference between a HOMO level and a LUMO level of layers of an OLED according to another embodiment of the present invention.

### DETAILED DESCRIPTION OF THE INVENTION

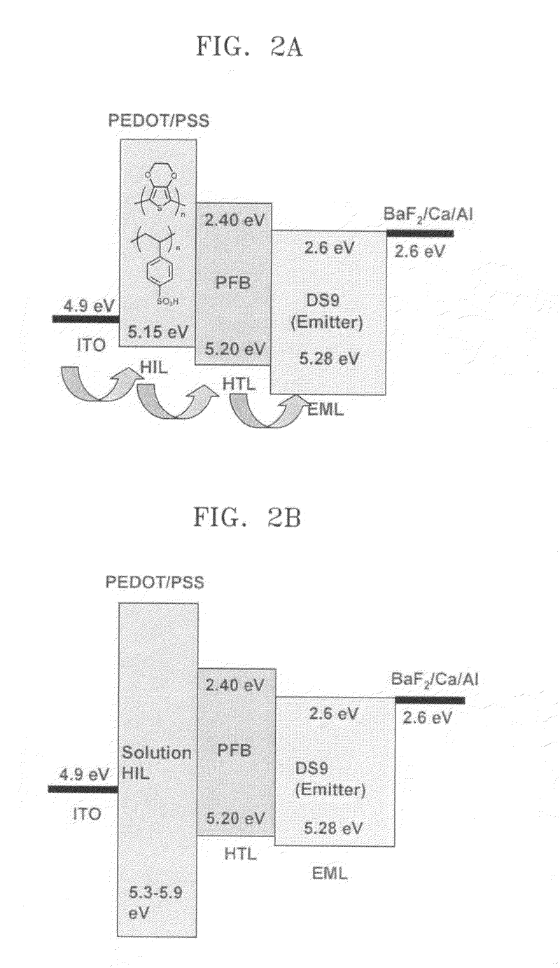

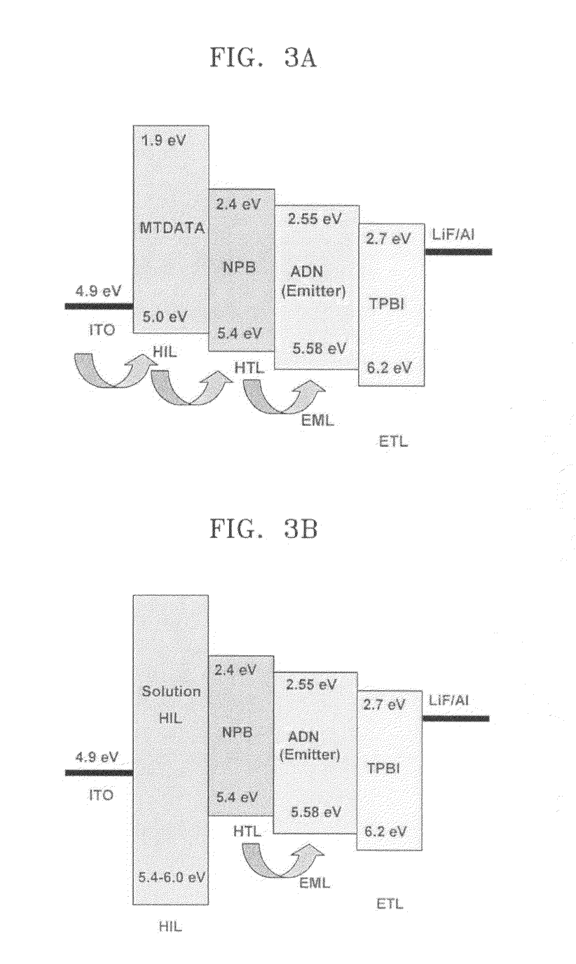

One example of organic light emitting device (OLED) is an OLED in which a hole injection layer (HIL) is formed of a polymer that has undergone through a solution process. In this type, PEDOT-PSS is coated on the ITO electrode and an emitting layer is formed thereon, or a HTL formed of poly(9,9-dioctylfluorene-co-bis-(4-butylphenyl-bis-N,N-phenyl-1,4-phenylenediamine (PFB) is formed between PEDOT-PSS and a fluorine polymer emitting layer such as poly(spirofluorene-co-phenoxazine (DS9) as illustrated in FIG. 2A. These types are generally designed such that holes are transported stepwise. Another example is an OLED manufactured by vacuum-deposition as illustrated in FIG. 3A, a HIL such as 4,4′4″-tris(3-methylphenylphenyl amino)triphenylamine (MTDATA) is deposited, and then a HTL such as N,N′-di(naphthalene-1-il)-N,N′-diphenyl benzidine (NPB) is sequentially deposited, and then an emitting layer (EML) such as 9,10-bis-(β-naphthyl)-anthracene (AND), and an electron transporting layer (ETL) such as 1,3,5-tris(N-phenylbenzimidazol-2-yl)benzene (TPBI) is deposited, and finally, a metal electrode is deposited to manufacture an OLED. In this OLED, holes also flow stepwise.

However, a HIL formed of a conducting polymer composition according to an embodiment of the present invention forms an ohmic contact with the ITO, and once the conducting polymer composition is coated on the ITO, a built-in-potential as much as the difference between the HIL and the ITO electrode in the OLED occurs. Accordingly, the conducting polymer composition substantially plays a key role in hole injection. (T. M. Brown et al., APL, 75, 1679 (1999)) Thus, in this case, the absolute value of the higher the work function, the ionization energy or HOMO of the HIL, the easier the hole injection to the emitting layer and the HTL. As illustrated in FIGS. 2B and 3B, the present invention provides an OLED for facilitating hole injection to the HTL by increasing the absolute value of the work function, the ionization energy or the HOMO of a thin layer, which is obtained by coating the conducting polymer composition, to be greater than those of the HTL of a conventional OLED through a solution process.

The present invention will now be described more fully.

An organic light emitting device (OLED) according to an embodiment of the present invention comprises a first electrode; a second electrode; and a hole injection layer (HIL), a hole transporting layer (HTL), and an emitting layer interposed between the first electrode and the second electrode, wherein the absolute value of the work function, the ionization potential (IP), or a highest occupied molecular orbital (HOMO) level of the HIL is greater than the absolute value of the HOMO level of the HTL.

The HIL may be formed of a conducting polymer compound including a conducting polymer and a fluorinated or perfluorinated ionomer.

According to the report reported in APL, 75, 1679 (1999) by T. M. Brown et al, the electro-absorption (EA) responses (at a DC voltage of 2.95 eV) of an OLED having a (a) indium tin oxide (ITO)/poly(4,4′-diphenylene diphenylvinylene(PDPV)PDPV/Ca—Al structure, and of an OLED having a (b) indium tin oxide (ITO)/poly(3,4-ethylenedioxythiophene)-poly(4-styrene-sulfonate) (PEDOT:PSS)/PDPV/Ca—Al structure in which PEDOT-PSS is coated on the ITO (first electrode) was observed. As such, when ΔI/I is 0, the DC bias voltage in case of (a) is 2.0 V, which is the difference of the absolute values of HOMO levels between the ITO layer and the Ca—Al layer (second electrode). In case of (b), the DC bias voltage is 2.5 V, which is the difference between the absolute values of HOMO levels of the PEDOT:PSS layer and the second electrode. This indicates that when a HIL formed of a conducting polymer composition is formed on an ITO layer (first electrode), the work function of the first electrodes is substantially decided not by the ITO, but by the HIL.

When a solution HIL is used, the work function of an anode is influenced by the work function of the solution HIL such as by the PEDOT:PSS layer rather than by the ITO layer. Thus, when a solution HIL is included, no matter what kind of energy barrier that there may be with respect to the ITO, an ohmic contact between the ITO and the HIL is maintained that is not influenced by the energy barrier substantially. Accordingly, even when a HIL having a high work function is used, the energy barrier between the ITO layer and the HIL is hardly influenced.

Also, when the HIL used in the present invention is formed of a conducting polymer and a fluorinated ionomer, the fluorinated ionomer increases the absolute value of the ionization potential (IP). However, a vacuum level of the HIL shifted upward due to a dipole moment present in the fluorinated ionomer close to the ITO, and the difference between the work function of the ITO layer and the IP of the HIL is offset. As a result, the adhesive force between the ITO and the HIL becomes strong due to the ionic interaction between the ITO and the fluorinated ionomer, and there is no contact resistance between the hole injection layer and the ITO layer, and ohmic contact is maintained, and thus a hole injection barrier is not present even if there is a difference between the ionization potentials of the ITO layer and the HIL. Meanwhile, as the absolute level of the IP of the HIL is equal to or greater than the HTL, there is no energy barrier any more with respect to the HTL, and thus hole injection to the HTL becomes easier.

The difference of the absolute values of the work function, the IP or the HOMO level between the HIL and the HTL may be greater than 0.2 eV, preferably 0.7 eV. The closer the difference of the absolute values of the work function, the IP or the HOMO level between the HIL and the HTL is to 0 eV, the less the amount of holes injected from the HIL to the HTL, thereby reducing the effects of the present invention.

The absolute value of the HOMO level of the HIL may be 5.3 to 6.5 eV, and that of the lowest unoccupied molecular orbital (LUMO) of the HIL may be 0 to 5.2 eV. The level of the HOMO of the HTL may be 5.2 to 6.1 eV, and the level of LUMO of the HTL may be 0 to 3.5 eV. The absolute value of the HOMO level of the HIL should be always greater than or equal to the absolute value of the HOMO level of the HTL, and other conditions other than this can be selected independently.

The OLED according to an embodiment of the present invention may further comprise an electron transporting layer (ETL) between the emitting layer and the second electrode.

The electron mobility of the ETL may be from 1×10⁻⁵ cm²/Vs to 1×10⁻² cm²/Vs in an electric field of 800 to 1,000 (V/cm)^{1/2}. Since hole injection becomes easy in the OLED in the current embodiment of the present invention, electron injection should be preferably as easy as hole injection, and thus an ETL having high electron mobility is used to optimize charge balance, thereby significantly enhancing the efficiency or the lifetime of the OLED. For example, N,N′-di(naphtalne-1-il)-N,N′-diphenyl benzidine (NPB or α-NPD) is frequently used as a HIL having a hole mobility of about 1×10⁻³ cm²/Vs, according to the article by Hung et al, APL, 88, 064102 (2006). However, (tris(8-quinolinolato)-aluminium) (Alq3), which is conventionally used as the ETL, has low electron mobility of about 1×10⁻⁵ cm²/Vs, according to the article by Li et al. Adv. Mater. 14, 1317 (2002). Thus, it may need to increase the electron mobility. When the electron mobility of the ETL is less than 1×10⁻⁵ cm²/Vs, electron injection is insufficient, thereby not maintaining the charge balance. When the electron mobility of the ETL is greater than 1×10⁻² cm²/Vs, electron injection becomes excessive, thereby not maintaining the charge balance.

According to another embodiment of the present invention, the absolute value of the IP of the HIL can be set to be equal to or greater than the absolute value of the IP of the HTL, and the electron mobility of the ETL can be set to be 0.01 to 10 times the hole mobility of the HTL in an electric field from 800 to 1,000 (V/cm)^{1/2}. Also, in this case, hole and electron injection becomes easier, thereby significantly increasing the luminous efficiency and the lifetime of the OLED.

When the electron mobility of the ETL is less than 0.01 times the hole mobility of the HTL, electron injection and electron transportation becomes poorer than hole injection and hole transportation, and thus the effect expected from the present invention cannot be obtained. When the electron mobility of the ETL is greater than 10 times the hole mobility of the HTL, electron injection and electron transportation becomes easier than hole injection and hole transportation, and thus it is not efficient in view of the luminous efficiency or the lifetime of the OLED.

Examples of the material for the ETL included in the OLED of the present invention may include: bis(10-hydroxybenzo[h]quinolinato)beryllium (Bebq2), 1,3,5-tris(N-phenylbenzimidazol-2-yl)benzene) (TPBI), terfluorene (E3), bis(phenylquinoxaline), starburst tris(phenylquinoxaline), and derivatives of these.

Examples of the material for the hole transportation included in the OLED of the present invention may include an arylamine derivative or a polymer containing the same. Preferably, the HTL includes carbazole or derivatives thereof, a phenoxazine or a derivative thereof, a phenothiazine or a derivative thereof, or polymers containing a carbazole group, phenoxazine group, or a phenothiazine group. More preferably, the HTL includes at least one selected from the group consisting of 1,3,5-tricarbazolylbenzene, 4,4′-scarbazolylbiphenyl, polyvinylcarbazole, m-biscarbazolylphenyl, 4,4′-biscarbazolyl-2,2′-dimethylbiphenyl, 4,4′,4″-tri(N-carbazolyl)triphenylamine, 1,3,5-tri(2-carbazolylphenyl)benzene, 1,3,5-tris(2-carbazolyl-5-methoxyphenyl)benzene, bis(4-carnazolylphenl)silane, N,N′-bis(3-methylphenyl)-N,N′-diphenyl-[1,1-biphenyl]-4,4′diamine (TPD), N,N′-di(naphthalne-1-il)-N,N′-diphenylbenzidine (α-NPD), NPB, IDE320 (available from Idemitsu Corporation), poly(9,9-dioctylfluorene-co-N-(4-butylphenyl)diphenylamine), and poly(9,9-dioctylfluorene-co-bis-(4-butylphenyl-bis-N,N-phenyl-1,4-phenylenediamine), poly(9,9-dioctylefluorene-co-N,N-di(phenyl)-N,N-di(3-carboethoxyphenyl))benzidine, and derivatives thereof.

The conducting polymer included in the HIL included in the OLED of the present invention may be at least one selected from the group consisting of polythiophene, poly(3,4-ethylene dioxythiophene) (PEDOT), polyaniline, polypyrrole, polyacetylene, derivatives thereof, and a self-doped conducting polymer.

The self-doped conducting polymer has a repeating unit represented by Formula 1 below having a degree of polymerization of 10 to 10,000,000:

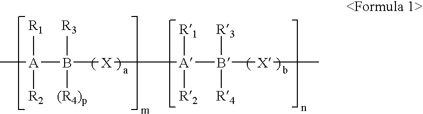

where 0<m<10,000,000, 0<n<10,000,000, 0≦a≦20, 0≦b≦20, and 2≦p≦10,000,000;

at least one of R₁, R₂, R₃, R′₁, R′₂, R′₃, and R′₄ includes an ionic group, and A, B, A′, and B′ are each independently selected from C, Si, Ge, Sn, or Pb;

R₁, R₂, R₃, R′₁, R′₂, R′₃, and R′₄, are each independently selected from the group consisting of hydrogen, halogen, a nitro group, a substituted or unsubstituted amino group, a cyano group, a substituted or unsubstituted C₁-C₃₀ alkyl group, a substituted or unsubstituted C₁-C₃₀ alkoxy group, a substituted or unsubstituted C₆-C₃₀ aryl group, a substituted or unsubstituted C₆-C₃₀ arylalkyl group, a substituted or unsubstituted C₆-C₃₀ aryloxy group, a substituted or unsubstituted C₂-C₃₀ heteroaryl group, a substituted or unsubstituted C₂-C₃₀ heteroarylalkyl group, a substituted or unsubstituted C₂-C₃₀ heteroaryloxy group, a substituted or unsubstituted C₅-C₃₀ cycloalkyl group, a substituted or unsubstituted C₅-C₃₀ heterocycloalkyl group, a substituted or unsubstituted C₁-C₃₀ alkylester group, and a substituted or unsubstituted C₆-C₃₀ arylester group;

R₄ is formed of a conjugated conducting polymer chain; and

X and X′ are each independently selected from the group consisting of a simple bond, O, S, a substituted or unsubstituted C₁-C₃₀ alkylene group, a substituted or unsubstituted C₁-C₃₀ heteroalkylene group, a substituted or unsubstituted C₆-C₃₀ arylene group, a substituted or unsubstituted C₆-C₃₀ arylalkylene group, a substituted or unsubstituted C₂-C₃₀ heteroarylene group, a substituted or unsubstituted C₂-C₃₀ heteroarylakylene group, a substituted or unsubstituted C₅-C₂₀ cycloalkylene group, a substituted or unsubstituted C₅-C₃₀ heterocycloalkylene group, and a substituted or unsubstituted C₆-C₃₀ arylester group.

Preferably, the ionic group comprises an anionic group such as PO₃²⁻, SO₃⁻, COO⁻, I⁻, CH₃COO⁻, etc. and a cationic group selected from a metal ion such as Na⁺, K⁺, Li⁺, Mg⁺², Zn⁺², Al⁺³; and an organic ion such as H⁺, NH₄⁺, CH₃(—CH₂—)ₙO⁺ (n is an integer from 0 through 50), which is in pair with the cationic group.

Preferably, in the self-doped conducting polymer of Formula 1, at least one of R₁, R₂, R₃, R′₁, R′₂, R′₃, and R′₄ is a fluorine or a group substituted with fluorine.

R₄ can be any conjugated conducting polymer chain. Examples of R₄ include, but are not limited to, arylamine, aryl, fluorene, aniline, thiophene, phenylene, and acetylene.

The fluorinated ionomer included in the HIL of the OLED in the present invention includes a polymer having at least one of the repeating units represented by Formulas 2 through 12:

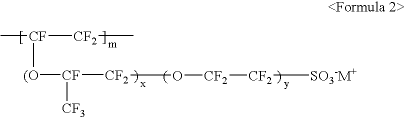

where m is an integer from 1 to 10,000,000, and x and y are each a number from 0 to 10, M⁺ is Na⁺, K⁺, Li⁺, H⁺, CH₃(CH₂)ₙNH₃⁺ (n is an integer from 0 to 50), NH₄⁺, NH₂⁺, NHSO₂CF₃⁺, CHO⁺, C₂H₅OH⁺, CH₃OH⁺, and RCHO⁺ where R is an alkyl group, that is, CH₃(CH₂)ₙ⁻ where n is an integer from 0 to 50.

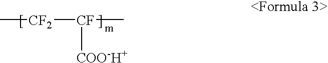

where m is an integer from 1 to 10,000,000.

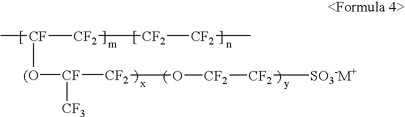

where 0<m≦10,000,000, 0≦n<10,000,000, and x and y are each a number from 0 to 20, M⁺ is Na⁺, K⁺, Li⁺, H⁺, CH₃(CH₂)ₙNH₃⁺ (n is an integer from 0 to 50), NH₄⁺, NH₂⁺, NHSO₂CF₃⁺, CHO⁺, C₂H₅OH⁺, CH₃OH⁺, and RCHO⁺ where R is an alkyl group, that is, CH₃(CH₂)ₙ⁻ where n is an integer from 0 to 50.

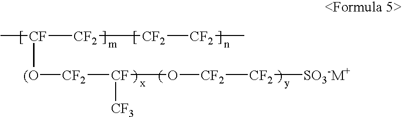

where 0<m≦10,000,000, 0≦n<10,000,000, and x and y are each 0 to 20, M⁺ is Na⁺, K⁺, Li⁺, H⁺, CH₃(CH₂)ₙNH₃⁺ (n is an integer from 0 to 50), NH₄⁺, NH₂⁺, NHSO₂CF₃⁺, CHO⁺, C₂H₅OH⁺, CH₃OH⁺, and RCHO⁺ where R is an alkyl group, that is, CH₃(CH₂)ₙ⁻ where n is an integer from 0 to 50.

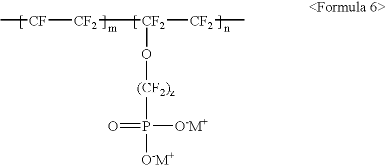

where 0<m≦10,000,000, 0≦n<10,000,000, and x and y are each a number from 0 to 20, M⁺ is Na⁺, K⁺, Li⁺, H⁺, CH₃(CH₂)ₙNH₃⁺ (n is an integer from 0 to 50), NH₄⁺, NH₂⁺, NHSO₂CF₃⁺, CHO⁺, C₂H₅OH⁺, CH₃OH⁺, and RCHO⁺ where R is an alkyl group, that is, CH₃(CH₂)ₙ⁻ where n is an integer from 0 to 50.

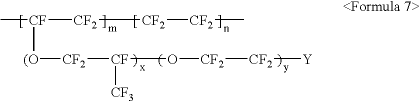

where 0<m≦10,000,000, 0≦n<10,000,000, and x and y are each a number from 0 to 20, M⁺ is Na⁺, K⁺, Li⁺, H⁺, CH₃(CH₂)ₙNH₃⁺ (n is an integer from 0 to 50), NH₄⁺, NH₂⁺, NHSO₂CF₃⁺, CHO⁺, C₂H₅OH⁺, CH₃OH⁺, and RCHO⁺ where R is an alkyl group, that is, CH₃(CH₂)ₙ⁻ where n is an integer from 0 to 50.

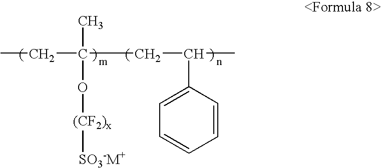

where 0<m≦10,000,000, 0≦n<10,000,000, and x and y are each a number from 0 to 20, M⁺ is Na⁺, K⁺, Li⁺, H⁺, CH₃(CH₂)ₙNH₃⁺ (n is an integer from 0 to 50), NH₄⁺, NH₂⁺, NHSO₂CF₃⁺, CHO⁺, C₂H₅OH⁺, CH₃OH⁺, and RCHO⁺ where R is an alkyl group, that is, CH₃(CH₂)ₙ⁻ where n is an integer from 0 to 50.

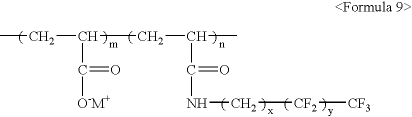

where 0<m≦10,000,000, 0≦n<10,000,000, and x and y are each a number from 0 to 20, M⁺ is Na⁺, K⁺, Li⁺, H⁺, CH₃(CH₂)ₙNH₃⁺ (n is an integer from 0 to 50), NH₄⁺, NH₂⁺, NHSO₂CF₃⁺, CHO⁺, C₂H₅OH⁺, CH₃OH⁺, and RCHO⁺ where R is an alkyl group, that is, CH₃(CH₂)ₙ⁻ where n is an integer from 0 to 50.

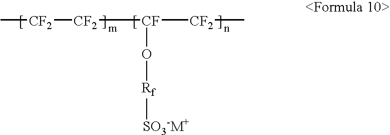

where 0≦m<10,000,000, 0<n≦10,000,000, R_{f}═—(CF₂)_{z}— (z is an integer from 1 to 50, except 2), —(CF₂CF₂O)_{z}CF₂CF₂— (z is an integer from 1 to 50), —(CF₂CF₂CF₂O)_{z}CF₂CF₂— (z is an integer from 1 to 50), M⁺ is Na⁺, K⁺, Li⁺, H⁺, CH₃(CH₂)ₙNH₃⁺ (n is an integer from 0 to 50), NH₄⁺, NH₂⁺, NHSO₂CF₃⁺, CHO⁺, C₂H₅OH⁺, CH₃OH⁺, and RCHO⁺ where R is an alkyl group, that is, CH₃(CH₂)ₙ⁻ where n is an integer from 0 to 50.

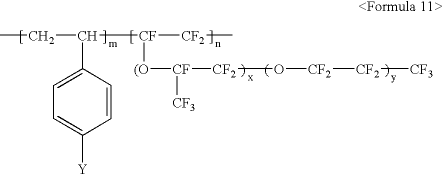

where m and n 0≦m<10,000,000, 0<n≦10,000,000, x and y are each a number from 0 to 20, Y is one selected from the group consisting of —SO₃⁻M⁺, —COO⁻M⁺, —SO₃⁻NHSO₂CF3⁺, and —PO₃²⁻(M⁺)₂, M⁺ is Na⁺, K⁺, Li⁺, H⁺, CH₃(CH₂)ₙNH₃⁺ (n is an integer from 0 to 50), NH₄⁺, NH₂⁺, NHSO₂CF₃⁺, CHO⁺, C₂H₅OH⁺, CH₃OH⁺, and RCHO⁺ where R is an alkyl group, that is, CH₃(CH₂)ₙ⁻ where n is an integer from 0 to 50.

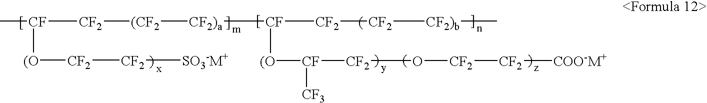

where 0≦m<10,000,000, 0<n≦10,000,000, M⁺ is Na⁺, K⁺, Li⁺, H⁺, CH₃(CH₂)ₙNH₃⁺ (n is an integer from 0 to 50), NH₄⁺, NH₂⁺, NHSO₂CF₃⁺, CHO⁺, C₂H₅OH⁺, CH₃OH⁺, and RCHO⁺ where R is a C₁-C₅₁ alkyl group, that is, CH₃(CH₂)ₙ⁻ where n is an integer from 0 to 50.

Examples of the unsubstituted C₁-C₃₀ alkyl group used in the present invention are linear or branched methyl, ethyl, propyl, isobutyl, sec-butyl, tert-butyl, pentyl, iso-amyl, hexyl, etc. Examples of the substituted C₁-C₃₀ alkyl group are linear or branched methyl, ethyl, propyl, isobutyl, sec-butyl, tert-butyl, pentyl, iso-amyl, hexyl, etc. at least one hydrogen atom of which is substituted with a halogen atom, a hydroxyl group, a nitro group, a cyano group, a substituted or unsubstituted amino group (—NH₂, —NH(R), —N(R′)(R″), where R′ and R″ are each independently a C₁-C₂₀ alkyl group), an amidino group, a hydrazine or a hydrazone group, a carboxyl group, a sulfonic acid group, a phosphoric acid group, a C₁-C₂₀ alkyl group, a C₁-C₂₀ halogenized alkyl group, a C₁-C₂₀ alkenyl group, a C₁-C₂₀ alkynyl group, a C₁-C₂₀ heteroalkyl group, a C₆-C₂₀ aryl group, a C₆-C₂₀ arylalkyl group, a C₆-C₂₀ heteroaryl group, and a C₆-C₂₀ heteroarylalkyl group.

The heteroalkyl group used in the present invention refers to alkyl group in which at least one carbon atom, preferably, a C1-C5 carbon atom, of the main chain, is substituted with a hetero atom such as an oxygen atom, a sulfur atom, a nitrogen atom, a phosphorus atom, etc.

The aryl group used in the present invention refers to a carbocyclic aromatic system including at least one aromatic ring, and the rings are attached together using a pendant method, or are fused. Examples of the aryl group include an aromatic group such as phenyl, naphthyl, tetrahydronaphthyl, etc., and at least one hydrogen atom among the aryl group can also be substituted with the same substitution group as in the case of the alkyl group.

The heteroaryl group used in the present invention refers to a C5-C30 cyclic aromatic system that includes one to three hetero atoms selected from N, O, P, and S, wherein the rest of the ring atoms are C, and the rings are attached together using a pendant method, or are fused. At least one of a plurality of hydrogen atoms among the heteroaryl group can be substituted with the same substitution group as in the case of the alkyl group.

The alkoxy group used in the present invention refers to a radical-O-alkyl, and the alkyl here is as defined above. Examples of the alkoxy group include methoxy, ethoxy, propoxy, isobutyloxy, sec-butyloxy, pentyloxy, iso-amyloxy, hexyl oxy, etc., and at least one hydrogen atom of the alkoxy group can be substituted with the same substitution group as in the case of the alkyl group.

The heteroalkoxy group used in the present invention is substantially the same as the alkoxy group, except that O, S, or N can be present in the alkyl chain. Examples of the heteroalkoxy group include CH₃CH₂OCH₂CH₂O—, C₄H₉OCH₂CH₂OCH₂CH₂O—, and CH₃O(CH₂CH₂O)ₙH.

The arylalkyl group used in the present invention refers to an aryl group as defined above, in which at least one of the hydrogen atoms is substituted with a radical such as methyl, ethyl, propyl, etc. Examples of the arylalkyl group are benzyl, phenylethyl, etc. At least one hydrogen atom of the arylalkyl group can be substituted with the same substitution group as in the case of the alkyl group.

The heteroarylalkyl group used in the present invention refers to a heteroaryl group in which a portion of the hydrogen atom is substituted with a lower alkyl group. At least one hydrogen atom of the heteroarylalkyl group may be substituted with the same substitution group.

The aryloxy group used in the present invention refers to radical-O-aryl, and the aryl is defined as above. Examples of the aryloxy group include phenoxy, naphthoxy, anthracenyl oxy, phenanthrenyl oxy, fluorenyl oxy, indenyl oxy, etc. At least one hydrogen atom of the aryloxy group may be substituted with the same substitution group as in the case of the alkyl group.

The heteroaryloxy group used in the present invention refers to radical-O-heteroaryl, and the heteroaryl is as defined above. Examples of the heteroaryloxy group include benzyl oxy, phenylethyloxy, etc., and at least one hydrogen atom of the heteroaryloxy group can be substituted with the same substitution group as in the case of the alkyl group.

The cycloalkyl group used in the present invention refers to a C5-C30 univalent monocyclic system. At least one hydrogen atom in the cycloalkyl group can be substituted with the same substitution group as in the case of the alkyl group.

The heterocycloalkyl group used in the present invention refers to a C5-30 univalent monocyclic system including one to three hetero atoms selected from N, O, P, and S, wherein the rest of the rings are C atoms. At least one of the hydrogen atoms in the cycloalkyl group may be substituted with the same substitution group as in the case of the alkyl group.

The alkylester group used in the present invention refers to a functional group in which an alkyl group and an ester group are combined, and the alkyl group is as defined above.

The heteroalkylester group used in the present invention refers to a functional group in which a heteroalkyl group and an ester group are combined, and the heteroalkyl group is as defined above.

The arylester group used in the present invention refers to a functional group in which an aryl group and an ester group are combined, and the aryl group is as defined above.

The heteroarylester group used in the present invention refers to a functional group in which a heteroaryl group and an ester group are combined, and the heteroaryl group is as defined above.

The amino group used in the present invention refers to —NH₂, —NH(R), or —N(R′)(R″), and R′ and R″ are each C1-C10 alkyl groups.

The halogen used in the present invention may be fluorine, chlorine, bromine, iodine, or astatine, but preferably fluorine.

Also, the HIL included in the OLED in the present invention may further include a third ionomer having a different structure than the conducting polymer and the fluorinated ionomer.

The backbone of the third ionomer includes a non conjugated and/or conjugated fluorocarbon. The third ionomer may include an ionic group of a polymer acid, that is, sulfonic acid, carboxyl acid, or phosphoric acid, etc.

The HIL used in embodiments of the present invention is preferably a composition including the compound of Formula 13 (polystyrenesulfonic acid-graft-polyaniline (PSSA-g-PANI)) and a fluorinated ionomer.

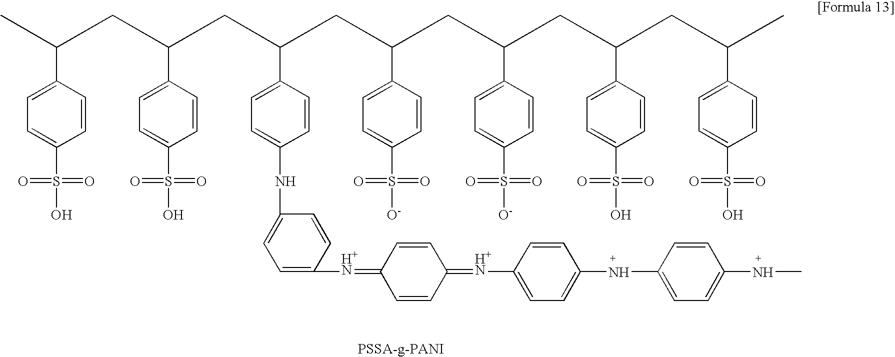

The HIL included in the OLED in embodiments of the present invention can be included through a solution process on the first electrode. The solution process refers to, for example, a process in which at least one organic material is dissolved or dispersed in a predetermined solvent, and then this resultant is coated on a predetermined substrate and dried and/or heated.

The solvent provides predetermined viscosity to the organic material. Any solvent that can dissolve or disperse the organic material used. Examples of the solvent include water, alcohol, toluene, xylene, chlorobenzene, chloroform, di-chloroethane, dimethylformamide, dimethyl sulfoxide, etc, but the solvent is not limited thereto.

Then, the solution containing the organic material is coated on the substrate, and the coating method may be a well known method such as spin coating, dip coating, spray printing, ink-jet printing, nozzle printing, etc., but the coating method is not limited thereto. Next, the coated layer is dried and/or heated.

The OLED according to an embodiment of the present invention may further include a hole blocking layer between the emitting layer and the ETL.

FIG. 2A is a diagram of an energy band illustrating the difference between the HOMO level and the LUMO level of layers of a conventional OLED. The HIL includes PEDOT, the HTL includes poly(9,9-dioctylfluorene-co-bis-(4-butylphenyl-bis-N,N-phenyl-1,4-phenylenediamine (PFB), and the emitting layer includes poly(spirofluorene-co-phenoxazine) (DS9). The absolute value of the HOMO level of the HTL is 5.20 eV, and the absolute value of the HOMO level of the HIL is 5.15 eV, which is less than that of the HTL.

FIG. 2B is a diagram of an energy band illustrating the difference between the HOMO level and the LUMO level of layers of an OLED according to an embodiment of the present invention. The HIL includes a conducting polymer composition including a conducting polymer and a fluorinated ionomer, and the HTL includes PFB, and the emitting layer includes DS9. The absolute value of the HOMO level of the HTL is 5.20 eV, and the absolute value of the HOMO level of the HIL is 5.3 to 5.9 eV, which is greater than that of the HTL.

FIG. 3A is a diagram of an energy band illustrating the difference between the HOMO level and the LUMO level of layers of a conventional OLED where the HIL includes (4,4′,4″-tris(3-methylphenylphenyl amino)triphenylamine (MTDATA), the HTL includes NPB, the emitting layer includes (9,10-bis-(β-naphthyl)-anthracene) (AND), and the ETL includes TPBI. The absolute value of the HOMO level of the HTL is 5.4 eV, and the absolute value of the HOMO level of the HIL is 5.0 eV, which is less than that of the HTL.

FIG. 3B is a diagram of an energy band illustrating the difference between the HOMO level and the LUMO level of layers of an OLED according to an embodiment of the present invention. The HIL includes a conducting polymer composition including a conducting polymer and a fluorinated ionomer, the HTL includes NPB, the emitting layer includes AND, and the ETL includes TPBI. The absolute value of the HOMO level of the HTL is 5.4 eV, and the absolute value of the HOMO level of the HIL is 5.4 to 6.0 eV, which is greater than that of the HTL.

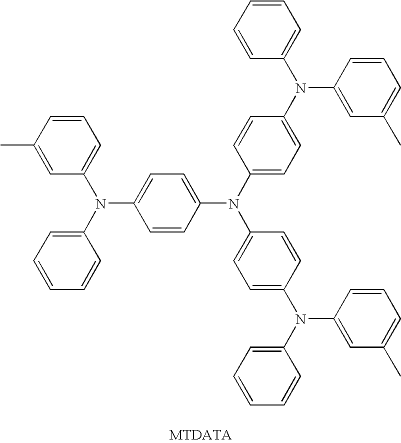

Hereinafter, an organic light emitting device including a conducting polymer composition of the present invention and a method of manufacturing the same will be described, according to embodiments of the present invention.

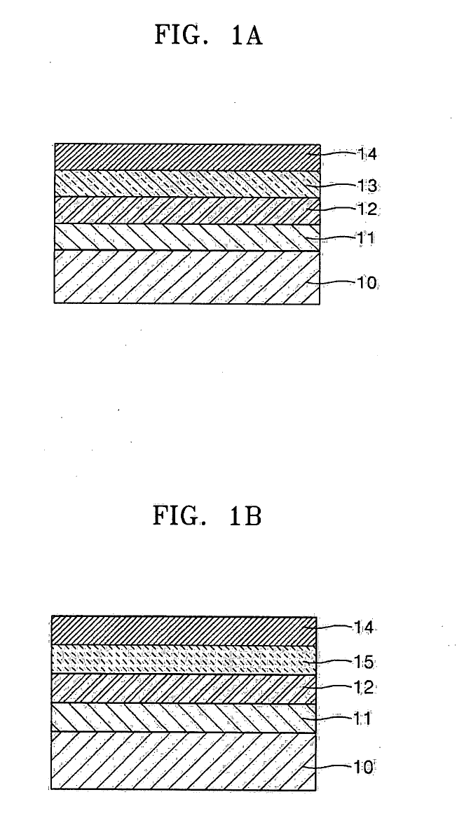

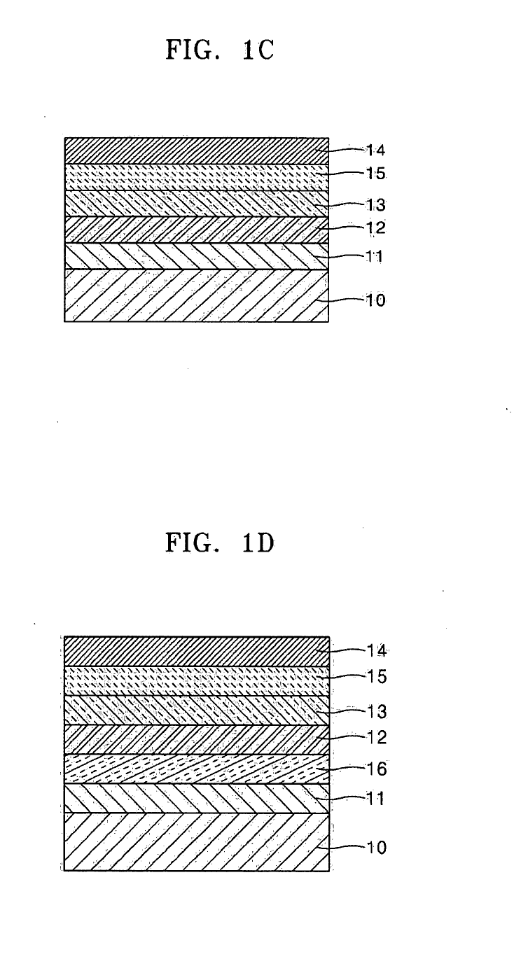

FIGS. 1A through 1D illustrate a layered structure of an OLED according to embodiments of the present invention.

FIG. 1A illustrates an OLED including an emitting layer 12 formed on a first electrode 10, a HIL 11 (also called a buffer layer) between the first electrode 10 and the emitting layer 12, a hole blocking layer (HBL) 13 on the emitting layer 12, and a second electrode 14 on the HBL 13.

FIG. 1B illustrates an OLED having the same structure as that of FIG. 1A, except that an ETL 15, instead of the HBL 13, is formed on the emitting layer 12.

FIG. 1C illustrates an OLED having the same structure as that of FIG. 1A, except that a two-layers sequentially formed HBL 13 and an ETL 15, instead of an HBL 13, is formed on the emitting layer 12.

FIG. 1D illustrates an OLED having the same structure as that of FIG. 1C, except that an HTL 16 is further formed between the HIL 11 and the emitting layer 12. The HTL 16 prevents the injection of impurities from the HIL 11 to the emitting layer 12.

The OLEDs illustrated in FIGS. 1A through 1D can be formed using a common manufacturing method, but the OLEDs are not particularly limited thereto.

The electron mobility in a conventional OLED using Alq3 is generally 10⁻⁵ cm²/Vs. However, the electron transporting materials that can be used in the present invention have an electron mobility of about 10⁻⁴ to 10⁻³ cm²/Vs.

The hole mobility and the electron mobility are measured usually using a time-of-flight photocurrent method. In time-of-flight photocurrent method, light is radiated through a laser to an electrode of an OLED to generate photocarriers and an electric field is applied so that the generated photocarriers move to the other electrode, and the transition time of the movement of the photocarriers from one electrode to the other electrode is measured. Here, when the thickness of the OLED and an intensity of the electric field are known, the hole and electron mobility can be calculated. In other words, the hole and electron mobility can be calculated by dividing the thickness (the distance the photocarriers move) of the OLED by the intensity of the electric field and the transition time.

A method of manufacturing an OLED according an embodiment of the present invention is as follows.

First, a first electrode 10 is patterned and formed on a substrate (not shown). The substrate may be any substrate generally used in an OLED, and may be glass substrate or a transparent plastic substrate that has good transparency and surface leveling, can be easily handled, and is waterproof. The thickness of the substrate may be 0.3 to 1.1 mm.

The material forming the first electrode 10 is not particularly limited. When the first electrode is an anode, the anode is formed of a conductive metal or an oxide thereof that can easily inject holes. Examples of the material include ITO, indium zinc oxide (IZO), Ni, Pt, Au, and Ir.

The substrate on which the first electrode 10 is formed is washed and treated with ultraviolet (UV) ozone. The substrate is washed using an organic solvent such as isopropanol (IPA), acetone, etc.

Then a HIL 11 including a conducting polymer composition is formed on the first electrode 10 that is on the cleaned substrate. When the HIL 11 is formed, the contact resistance of the first electrode 10 and the emitting layer 12 is reduced, and the hole transporting capability from the first electrode 10 to the emitting layer 12 improves, thereby improving the turn-on voltage and the lifetime of the OLED.

The HIL 11 is formed by spin-coating a composition that is prepared by dissolving a conducting polymer composition, which is designed to have the energy band level of the OLED according to an embodiment of the present invention, in a solvent and then drying the composition. The composition for forming the HIL 11 is diluted using an organic solvent such as water, alcohol, dimethylformamide, dimethylsulfoxide, or dichloroethane to 0.5 to 10 weight %.

The thickness of the HIL 11 may be 5 to 1,000 nm, but preferably 10 to 100 nm. However the optimal thickness is preferably 50 nm. When the thickness of the HIL 11 is less than 5 nm, the HIL 11 is too thin for proper hole injection. When the thickness of the HIL is greater than 1,000 nm, transmittance of light may decrease.

An emitting layer 12 is formed on the HIL 11. The material forming the emitting layer 12 is not limited. Examples of the material forming the emitting layer 12 include oxadiazole dimer dyes (Bis-DAPOXP), spiro compounds (Spiro-DPVBi, Spiro-6P), triarylamine compounds, bis(styryl)amine (DPVBi), (DSA), 4,4′-bis(9-ethyl-3-carbazovinylene)-1,1′-biphenyl (BCzVBi), perylene, 2,5,8,11-tetra-tert-butylperylene (TPBe), 9H-carbazole-3,3′-(1,4-phenylene-di-2,1-ethene-diyl)bis[9-ethyl-(9C)] (BCzVB), 4,4-bis[4-(di-p-tolylamino)styryl]biphenyl (DPAVBi), 4-(di-p-tolylamino)-4′-[(di-p-tolylamino)styryl]stilbene (DPAVB), 4,4′-bis[4-(diphenylamino)stryl]biphenyl (BDAVBi), bis(3,5-difluoro-2-(2-pyridyl)phenyl-(2-carboxy pyridyl)iridium III (FIrPic), 3-(2-benzothiazolyl)-7-(diethylamino)coumarine (Coumarin 6) 2,3,6,7-tetrahydro-1,1,7,7,-tetramethyl-1H,5H,11H-10-(2-benzothiazolyl)quinolizino-[9,9 a,1gh]coumarine (C545T), N,N′-dimethyl-quinacridone (DMQA), tris(2-phenylpyridine)iridium(III) (Ir(ppy)₃), tetraphenylnaphtacene rubrene, tris(1-phenylisoquinoline)iridium(III) (Ir(piq)₃), bis(2-benzo[b]thiophene-2-il-pyridine)(acetylacetonate)iridium(III) (Ir(btp)₂(acac)), tris(dibenzoylmethane)phenanthroline europium(III) (Eu(dbm)₃(phen)), tris[4,4′-di-tert-butyl-(2,2′)-bipyridine]ruthenium(III)complex(Ru(dtb-bpy)₃*2(PF₆)), DCM1, DCM2, Eu(thenoyltrifluoroacetone)3 (Eu(TTA)3), and butyl-6-(1,1,7,7-tetramethyljulolidyl-9-enyl)-4H-pyran (DCJTB). Examples of a polymer light emitting material include aromatic compounds including nitrogen and polymer such as phenylene, phenylene vinylene, thiophene, fluorine, and spiro-fluorene polymers.

The thickness of the emitting layer 12 may be 10 nm to 500 nm, but preferably 50 nm to 120 nm. In the present embodiment, the thickness of the emitting layer 12 that is blue may be 70 nm. When the thickness of the emitting layer 12 is less than 10 nm, leakage current increases, thus decreasing efficiency, and when the thickness of the emitting layer 12 is greater than 500 nm, the turn-on voltage of the organic light emitting device increases to a larger value.

In some cases, the emitting layer 12 is formed by adding an emitting dopant to an emitting layer host. Examples of a fluorescent light emitting host includes tris(8-hydroxy-quinolato)aluminum (Alq3), 9,10-di(naphti-2-il)anthracene (AND), 3-tert-butyl-9,10-si(naphti-2-il)anthracene (TBADN), 4,4′-bis(2,2-diphenyl-ethene-1-il)-4,4′-dimethylphenyl (DPVBi), 4,4′-bisBis(2,2-diphenyl-ethene-1-il)-4,4′-dimethylphenyl (p-DMDPVBi), tert(9,9-diarylfluorene)s (TDAF), 2-(9,9′-spirobifluorene-2-il)-9,9′-spirobifluorene (BSDF), 2,7-bis(9,9′-spirobifluorene-2-il)-9,9′-spirobifluorene (TSDF), bis(9,9-diarylfluorene)s (BDAF), and 4,4′-bis(2,2-diphenyl-ethene-1-il)-4,4′-di-(tert-butyl)phenyl (p-TDPVBi). Examples of a phosphorescent host includes 1,3-bis(carbazole-9-il)benzene (mCP), 1,3,5-tris(carbazole-9-il)benzene (tCP), 4,4′,4″-tris(carbazole-9-il)triphenylamine (TcTa), 4,4′-bis(carbazole-9-il)biphenyl (CBP), 4,4′-bisBis(9-carbazolyl)-2,2′-dimethyl-biphenyl (CBDP), 4,4′-bis(carbazole-9-il)-9,9-dimethyl-fluorene (DMFL-CBP), 4,4′-bis(carbazole-9-il)-9,9-bisbis(9-phenyl-9H-carbazole)fluorene (FL-4CBP), 4,4′-bis(carbazole-9-il)-9,9-di-tolyl-fluorene (DPFL-CBP), 9,9-bis(9-phenyl-9H-carbazole)fluorene (FL-2CBP), etc.

The content of the dopant may vary according to the material forming the emitting layer 12, but the content is generally 30 to 80 parts by weight based on 100 parts by weight of the material for forming the emitting layer 12 (the total weight of the host and the dopant). When the content of the dopant is outside this range, the light emitting characteristic of the OLED device decreases. For example, 4,4′-bis[4-(di-p-tolylamino)styryl]biphenyl) (DPAVBi) can be used as a dopant, and 9,10-di(naph-2-tyl)anthracene (AND) or 3-tert-butyl-9,10-di(naph-2-tyl)anthracene (TBADN) can be used as the fluorescent host.

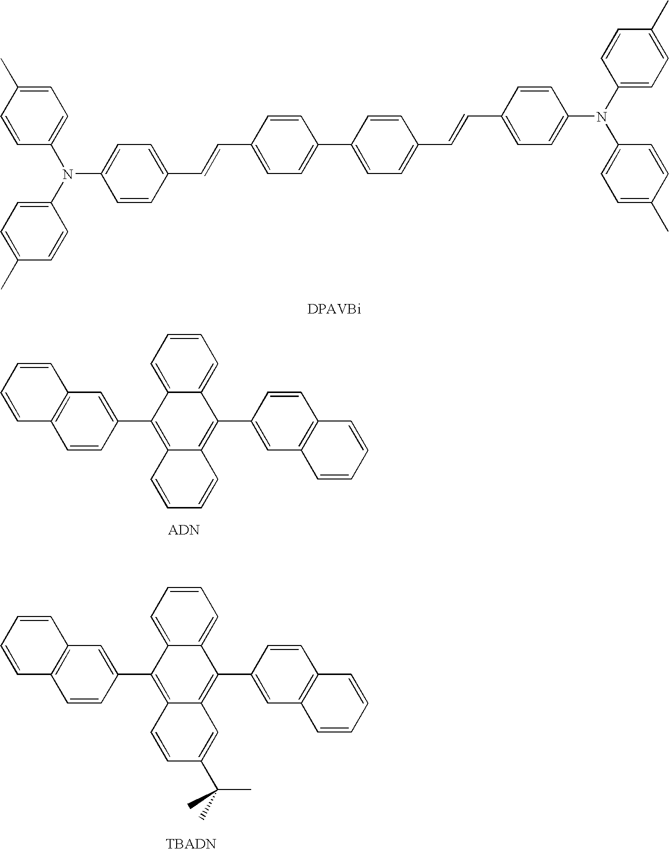

An HTL 16 can be formed between the HIL 11 and the emitting layer 12.

The material forming the HTL 16 may be any material such that the absolute value of the work function, the IP, or the absolute value of the HOMO level of the HIL 11 is equal to or greater than the absolute value of the HOMO level of the HTL, and may be, for example, a material including at least one selected from the group consisting of a compound having a carbazole group, a phenoxazine group, a phenothiazine group and/or arylamine group transporting holes, a phthalocyanine compound, and a triphenylene derivative. Specifically, the HTL 11 may be formed of at least one selected from the group consisting of 1,3,5-tricarbazolylbenzene, 4,4′-scarbazolylbiphenyl, polyvinylcarbazole, m-biscarbazolylphenyl, 4,4′-biscarbazolyl-2,2′-dimethylbiphenyl, 4,4′,4″-tri(N-carbazolyl)triphenylamine, 1,3,5-tri(2-carbazolylphenyl)benzene, 1,3,5-tris(2-carbazolyl-5-methoxyphenyl)benzene, bis(4-carnazolylphenl)silane, N,N′-bis(3-methylphenyl)-N,N′-diphenyl-[1,1-biphenyl]-4,4′diamine (TPD), N,N′-di(naphthalne-1-il)-N,N′-diphenylbenzidine (α-NPD), N,N′-diphenyl-N,N′-bis(1-naphthyl)-(1,1′-biphenyl)-4,4′-diamine (NPB), IDE320 (available from Idemitsu Corporation), poly(9,9-dioctylfluorene-co-N-(4-butylphenyl)diphenylamine), and poly(9,9-dioctylfluorene-co-bis-(4-butylphenyl-bis-N,N-phenyl-1,4-phenylenediamine, poly(9,9-dioctylefluorene-co-N,N-di(phenyl)-N,N-di(3-carboethoxyphenyl)benzidine, but the HTL 11 is not limited thereto.

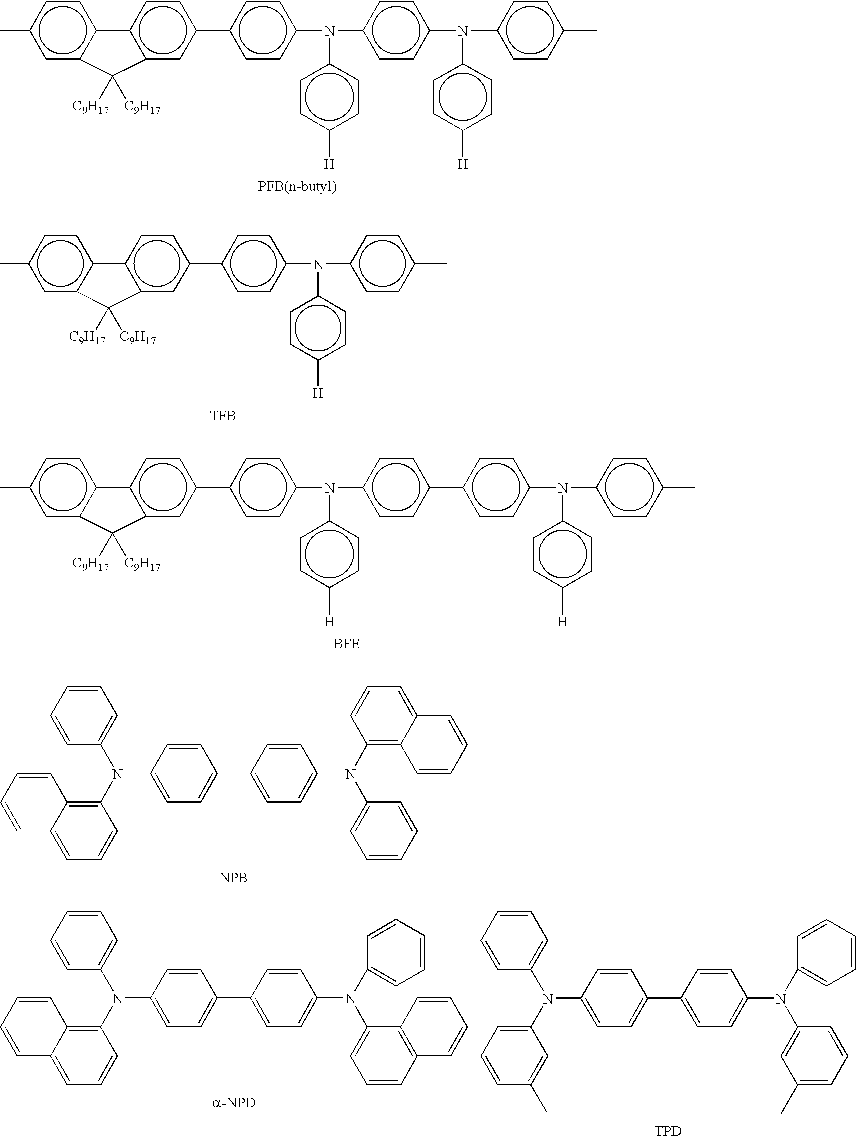

The HTL 16 has a thickness of 1 to 100 nm, but preferably 5 to 50 nm. According to the current embodiment of the present invention, the thickness of the HTL 16 is preferably less than 30 nm. When the thickness of the HTL 16 is less than 1 nm, the HTL 16 is too thin, and thus the hole transporting capability decreases. When the thickness of the HTL 16 is greater than 100 nm, the turn-on voltage of the OLED may increase.

A hole blocking layer 13 and/or an ETL 15 is formed on the emitting layer 12 using a deposition method or a spin coating method. The hole blocking layer 13 prevents excitons generated in a light emitting material from moving to the ETL 15 or prevents holes from moving to the ETL 15.

Examples of the material for forming the hole blocking layer 13 include a phenanthrolines compound (example: BCP, available from UDC), an imidazole compound, a triazole compound, an oxadiazole compound (example: PBD), an aluminum complex (available from UDC), BAlq represented by the formula below, 4,7-diphenyl-1,10-phenanthroline (Bphen), etc.

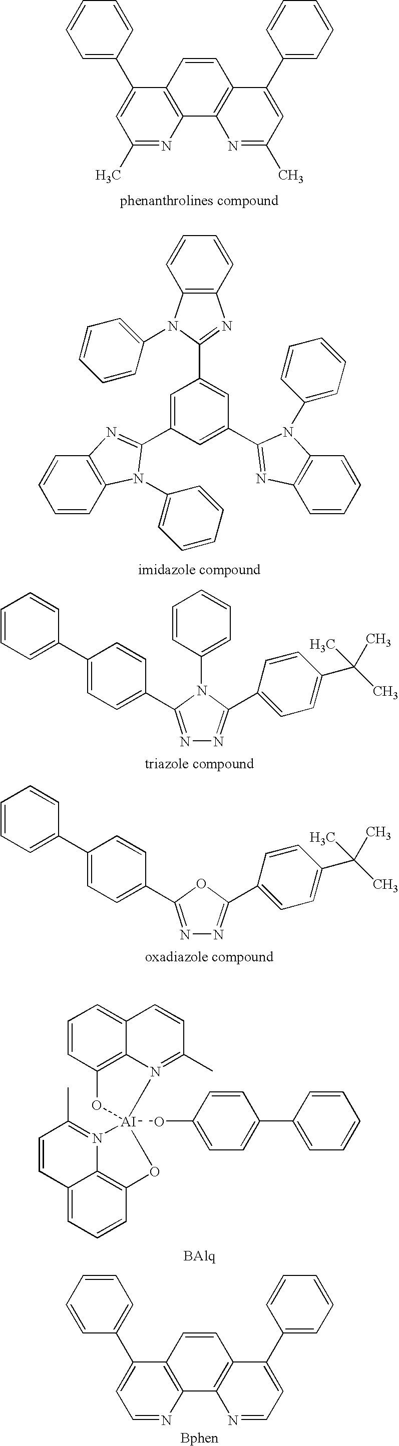

Examples of the material for forming the ETL 15 include an oxazole compound, an isooxazole compound, a triazole compound, an isothiazole compound, an oxadiazole compound, a thiadiazole compound, a perylene compound, an aluminum complex (example: Alq3 (tris(8-quinolinolato)-aluminum (tris(8-quinolinolato)-aluminium), BAlq, SAlq, Almq3, a gallium complex (example: Gaq′2OPiv, Gaq′2OAc, 2(Gaq′2)), BPQ (bis(phenylquinoxaline), TPQ (starburst tris(phenylquinoxaline) (TPQ1 of Formula below, TPQ2 of Formula below are examples of TPQ), 1,3,5-triazine, BCP of Formula below (2,9-dimethyl-4,7-diphenyl-1,10-phenanthroline), bis(10-hydroxybenzo[h]quinolinato)beryllium (BeBq2), TPBI (2,2′,2″-(1,3,5-benzinethriyl)-tris(1-phenyl-1-H-benzimidazole), E3 (terfluorene), etc. As described above, the material used for forming the HTL 16 in the art has usually a mobility of about 1×10⁻³ cm²/V.s, the mobility of the ETL 15 may be as high as possible. Accordingly, the hole transporting material may have a greater electron mobility than Alq3, which is about 1×10⁻⁵ cm²/V.s. According to the articles by Li et al. Adv. Mater., 14, 1317 (2002) and Hung et al. APL, 88, 064102 (2006), TPBI and E3 have a higher mobility than Alq3, and Beq3 also has a higher mobility (about 1×10⁻⁴ cm₂/V.s) than Alq3, and thus these materials can be used. Also, according to the article by M. Redecker et al. APL, 75, 109 (1999), TPQ1 and TPQ2 have an electron mobility of about 1×10⁻⁴ cm²/V.s, and thus can be used in the present invention.

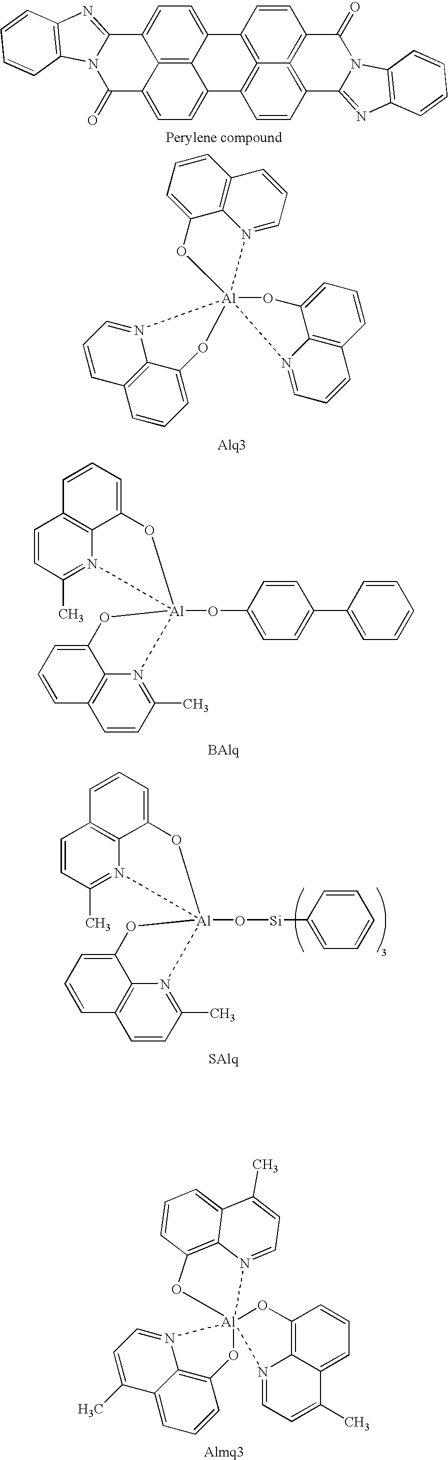

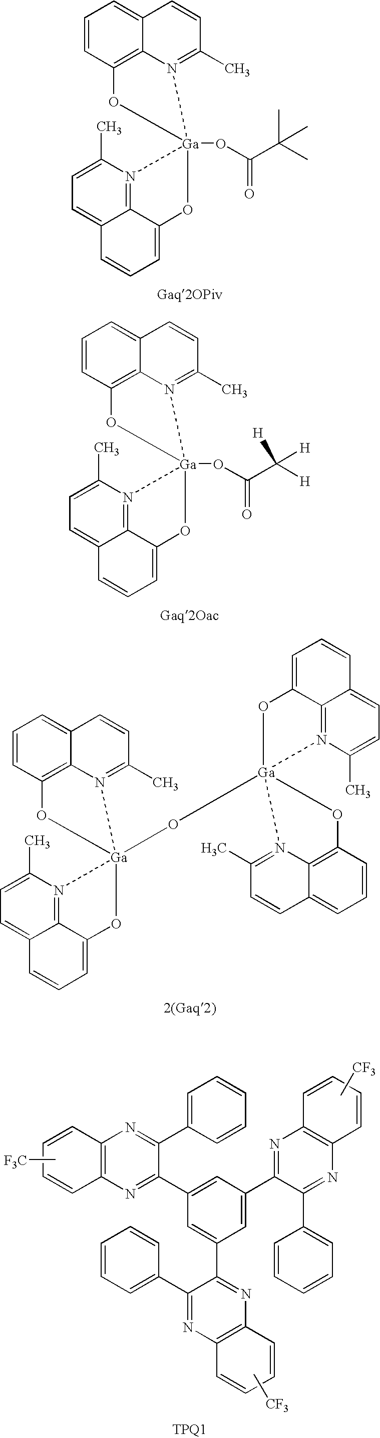

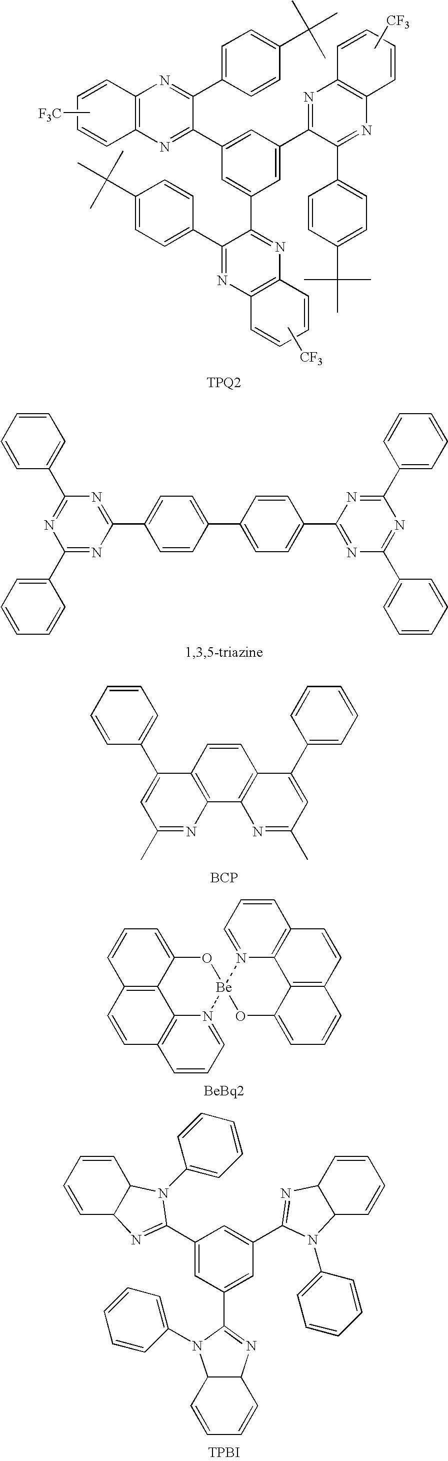

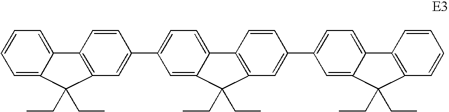

The thickness of the hole blocking layer 13 may be 5 nm to 100 nm, and the thickness of the ETL 15 may be 5 nm to 100 nm. When the thicknesses of the hole blocking layer 13 and the ETL 15 are outside of these ranges, the hole blocking ability and the electron transporting ability are insufficient.

Then, a second electrode 14 is formed on the resultant structure, and the resultant composition is encapsulated to complete an OLED.

The material for forming the second electrode 14 is not particularly limited. The second electrode 14 is formed of a metal having a low work function such as Li, Cs, Ba, Ca, Ca/Al, LiF/Ca, LiF/Al, BaF₂/Ca, Mg, Ag, Al, or an alloy of these or a multi-layer of these. The thickness of the second electrode 14 may be 50 to 3,000 Å.

The OLED according to the current embodiment of the present invention can be manufactured without a special apparatus or method, and can be manufactured using a conventional method using a conventional polymer or low molecular organic material.

Hereinafter, the present invention will be described in more detail with reference to the following examples. However, these examples are not intended to limit the scope of the invention.

### MANUFACTURING EXAMPLE 1

### Polyaniline (PANI) Conducting Polymer Composition

Polystyrenesulfonic acid-graft-polyanyline (PSSA-g-PANI) was polymerized as a self-doping conducting material using a known synthesizing method by [W. J. Bae et al. Chem. Comm., pp 2768-2769, 2003]. In the present embodiment, the weight ratio of the PSSA polymer chain and the grafted PANI chain was 1:0.15. The number-average molecular weight of PSSA-g-PANI was 35,000. The material was melted in water to 1.0 wt %. Then, a perfluorinated ionomer (PFI) that was dispersed to 5 wt % in a solvent with a volume ratio of water to alcohol of 0.45:0.55 was purchased from Aldrich Co. and isopropyl alcohol and 5 wt % PFI were mixed in a 1.0 wt % PSSA-g-PANI solution and used as a material for forming a HIL 11. This sample was called Sample A.

### MANUFACTURING EXAMPLE 2

### Manufacturing of PEDOT-PSS/PFI Conducting Polymer Composition

PEDOT-PSS (Model: Baytron P VP AI4083) which is refined to control the content of Na and sulfate to 5 ppm or less from H. C. Starck, which is a subsidiary of Bayer Aktien AG. Then PFI of Formula 14 was dispersed to 5 wt % in water and alcohol was purchased from Aldrich Co.

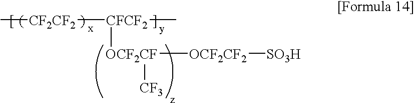

(where x=1300, y=200, x=1)

Then a HIL 11 was prepared with to various compositions of each of PEDOT-PSS/PFI. The ratios of the compositions were as listed in Table 1 below.

TABLE 1

| Sample Code | PEDOT/PSS/PFI |
|---|---|
| AI4083 | 1/6/0 |
| B | 1/6/1.6 |
| C | 1/6/3.2 |
| D | 1/6/6.3 |
| E | 1/6/12.7 |
| F | 1/6/25.4 |

### EVALUATION EXAMPLE 1

### Evaluation of Work Function of Conducting Polymer Film

The conducting polymer compositions obtained from Manufacturing Examples 1 and 2 were each spin-coated on an ITO substrate to form a thin layer to a thickness of 50 nm and heated in the air on a hot plate at 200° C. for 5 minutes, and the work function of the conducting polymer composition was evaluated. The Surface Analyzer Model AC2, which is a photoelectron spectrometer in air (PESA), manufactured by RIKEN KEIKI, Co. Ltd., was used as the evaluation apparatus. Sample A showed a work function of 5.6 eV, Sample B showed a work function of 5.55 eV, Sample C showed a work function of 5.63 eV, Sample D showed a work function of 5.72 eV, Sample E showed a work function of 5.79 eV, and Sample F showed a work function of 5.95 eV.

As evident from Evaluation Example 1, the work function of the thin layer of the conducting polymer composition according to the present invention can be increased.

### COMPARATIVE EVALUATION EXAMPLE 1

### Evaluation of Work Function of a Conducting Polymer Film

The work function was measured in the same way as in Evaluation Example 1, except that Baytron P VP AI4083 by H. C. Starck was used as an AC2 evaluation thin layer and the resulting work function was 5.20 eV. Also, the evaluation apparatus of the work function in vacuum showed a similar value of 5.15 eV obtained by using an ultraviolet photoelectron spectroscopy (UPS).

### EXAMPLE 1

A 15 Ω/cm² (150 nm) ITO glass substrate by Corning was cut to a size of 50 mm×50 mm×0.7 mm, washed using supersonic waves for 5 minutes in isopropanol alcohol and pure water, treated with ultraviolet ozone generator for 30 minutes and then used.

An HIL 11 was formed to a thickness of 50 nm on the ITO glass substrate by spin-coating a PEDOT-PSS/PFI conducting polymer composition solution obtained as from Manufacturing Example 2. NPB was vacuum-deposited on the HIL 11 to form an HTL 16 to a thickness of 30 nm.

An emitting layer 12 was formed to a thickness of 50 nm using ADN (9,10-di(naphti-2-il)anthracene, available from Lumtec Corp. LT-E403) as an emitting host and using DPAVBi (4,4-bis[4-(di-p-tolylamino)styryl]biphenyl, available from Lumtec Corp., LT-E605) as an emitting dopant. Then an ETL 15 was formed to a thickness of 30 nm on the emitting layer 12 by depositing Alq3 (tris(8-hydroxy-quinolinato)aluminum, available from Lumtec Corp. LT-E401) to manufacture an OLED. The manufactured OLED was called Sample 1.

### EXAMPLE 2

An OLED was manufactured in the same way as in Example 1, except that the ETL 15 was prepared using TPBI. The manufactured OLED was called Sample 2.

### EXAMPLE 3

An OLED was manufactured in the same way as in Example 1, except that the ETL 15 was prepared using Bebq2. The manufactured OLED was called Sample 3.

### COMPARATIVE EXAMPLE 1

A 15 Ω/cm² (150 nm) ITO glass substrate by Corning was cut to a size of 50 mm×50 mm×0.7 mm, washed using supersonic waves for 5 minutes each in isopropanol alcohol and pure water, treated with ultraviolet ozone generator for 30 minutes, and then used.

An HIL 11 was formed to a thickness of 50 nm on the ITO glass substrate by vacuum-depositing m-MTDATA (4,4′,4″-tris(N-3-methylphenyl-N-phenyl-amino triphenylamine, available from Lumtec Corp.). An HTL16 was formed to a thickness of 30 nm by vacuum-depositing NPB on the HIL 11.

An emitting layer 12 was formed to a thickness of 50 nm by ADN (9,10-di(naphti-2-il)anthracene, available from Lumtec Corp. LT-E403) as an emitting host and DPAVBi (4,4-bis[4-(di-p-tolylamino)styryl]biphenyl, available from Lumtec Corp., LT-E605) as an emitting dopant. Then an ETL 15 was formed to a thickness of 30 nm on the emitting layer 12 by depositing Alq3 (tris(8-hydroxy-quinolinato)aluminum, available from Lumtec Corp. LT-E401) in order to manufacture an OLED. The manufactured OLED was called Sample 4.

### COMPARATIVE EXAMPLE 2

An OLED was manufactured in the same manner as in Comparative Example 2, except that the ETL 15 was formed using TPBI. The manufactured OLED was called Sample 5.

### EVALUATION EXAMPLE 2

### Evaluation of Threshold Voltage and Efficiency

The threshold voltage and efficiency of Samples 1 through 5 were measured using a Keithley 238 source measurement unit and SpectraScan PR650 spectroradiometer. The measurement results are shown in Table 2 as follows.

### EVALUATION EXAMPLE 3

### Evaluation of Lifetime

The lifetimes of Samples 1 through 5 were evaluated. The lifetimes of Samples 1 through 5 were measured by measuring the brightness using a photodiode. The lifetime can be defined as the time over which the OLED's brightness will degrade to 50% of its original brightness. The results are shown in Table 2.

TABLE 2

| | Turn-on | Efficiency | Lifetime |
|---|---|---|---|
| HIL | voltage (V) | (cd/A) | (time at 1,000 cd/m²) |
| Sample 1 | 3.4 | 8.0 | About 1,200 |
| Sample 2 | 3.4 | 9.8 | About 2,000 |
| Sample 3 | 3.4 | 9.9 | About 2,500 |
| Sample 4 | 3.4 | 7.0 | About 800 |
| Sample 5 | 3.4 | 7.8 | About 1,000 |

In the OLED according to the present invention, the energy relationships between organic layers are controlled to facilitate hole injection and optimize the charge balance. Thus the efficiency of the OLED improves and the lifetime of the OLED increases.

While the present invention has been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. An organic light emitting device (OLED), comprising:
a first electrode;
a second electrode;
an emitting layer between the first electrode and the second electrode;
a hole injection layer between the first electrode and the emitting layer; and
a hole transporting layer between the hole injection layer and the emitting layer, the absolute value of the work function, the IP or the highest occupied molecular orbital (HOMO) level of the hole injection layer being greater than or equal to the absolute value of the HOMO level of the hole transporting layer.

2. The OLED of claim 1, wherein the hole injection layer is provided on the first electrode through a solution process.

3. The OLED of claim 1, wherein the hole injection layer is formed of a composition comprising a conducting polymer and at least one of a fluorinated ionomer and a perfluorinated ionomer.

4. The OLED of claim 1, wherein the difference of the absolute values of the work function, the IP, and the HOMO level between the hole injection layer and the hole transporting layer is 0.2 eV or greater.

5. The OLED of claim 1, wherein the absolute value of the HOMO level of the hole injection layer is 5.3 to 6.5 eV, and the absolute value of the lowest unoccupied molecular orbital (LUMO) level of the hole injection layer is 0 to 5.2 eV, and the absolute value of the level of the HOMO of the hole transporting layer is 5.2 to 6.1 eV, and the absolute value of the level of LUMO of the hole transporting layer is 0 to 3.5 eV.

6. The OLED of claim 3, wherein the conducting polymer is selected from the group consisting of polythiophene, poly(3,4-ethylene dioxythiophene) (PEDOT), polyaniline, polypyrrole, polyacetylene, derivatives thereof, and a self-doped conducting polymer.

7. The OLED of claim 1, further comprising an electron transporting layer (ETL) between the emitting layer and the second electrode.

8. The OLED of claim 1, wherein the electron mobility of the electron transporting layer is from 1×10⁻⁵ cm²/Vs to 1×10⁻² cm²/Vs in an electric field of 800 to 1,000 (V/cm)^{1/2}.

9. The OLED of claim 7, wherein the electron mobility of the electron transporting layer is 0.01 to 10 times the hole mobility of the hole transporting layer in an electric field of 800 to 1,000 (V/cm)^{1/2}.

10. The OLED of claim 1, wherein the electron transporting layer is formed of at least one selected from the group consisting of bis(10-hydroxybenzo[h]quinolinato)beryllium (Bebq2), 1,3,5-tris(N-phenylbenzimidazol-2-yl)benzene) (TPBI), terfluorene (E3), bis(phenylquinoxaline), starburst tris(phenylquinoxaline), and derivatives thereof.

11. The OLED of claim 1, wherein the hole transporting layer is formed of at least one of an arylamine derivative and a polymer containing the arylamine derivative.

12. The OLED of claim 1, wherein the hole transporting layer is formed of carbazole, or a derivative of carbazole, a phenoxazine, a derivative of phenoxazine, a phenothiazine, a derivative of phenothiazine, or a polymer containing at least one of a carbazole group, a phenoxazine group and a phenothiazine group.

13. The OLED of claim 1, wherein the hole transporting layer is formed of at least one selected from the group consisting of 1,3,5-tricarbazolylbenzene, 4,4′-scarbazolylbiphenyl, polyvinylcarbazole, m-biscarbazolylphenyl, 4,4′-biscarbazolyl-2,2′-dimethylbiphenyl, 4,4′,4″-tri(N-carbazolyl)triphenylamine, 1,3,5-tri(2-carbazolylphenyl)benzene, 1,3,5-tris(2-carbazolyl-5-methoxyphenyl)benzene, bis(4-carnazolylphenl)silane, N,N′-bis(3-methylphenyl)-N,N′-diphenyl-[1,1-biphenyl]-4,4′diamine (TPD), N,N′-di(naphthalne-1-il)-N,N′-diphenylbenzidine (α-NPD), N,N′-diphenyl-N,N′-bis(1-naphthyl)-(1,1′-biphenyl)-4,4′-diamine (NPB), IDE320 10 (available from Idemitsu Corporation), poly(9,9-dioctylfluorene-co-N-(4-butylphenyl)diphenylamine), poly(9,9-dioctylfluorene-co-bis-(4-butylphenyl-bis-N,N-phenyl-1,4-phenylenediamine, poly(9,9-dioctylefluorene-co-N,N-di(phenyl)-N,N-di(3-carboethoxyphenyl)benzidine, and derivatives thereof.

14. The OLED of claim 6, wherein the self-doped conducting polymer has a composition represented by Formula 1 having a degree of polymerization of 10 to 10,000,000: 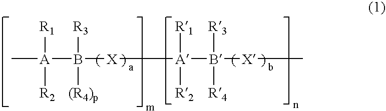
where 0<m<10,000,000, 0<n<10,000,000, 0≦a≦20, 0≦b≦20, and 2≦p≦10,000,000;
at least one of R₁, R₂, R₃, R′₁, R′₂, R′₃, and R′₄ includes an ionic group, and A, B, A′, and B′ are each independently selected from C, Si, Ge, Sn, or Pb;
R₁, R₂, R₃, R′₁, R′₂, R′₃, and R′₄, are each independently selected from the group consisting of a hydrogen, halogen, a nitro group, a substituted or unsubstituted amino group, a cyano group, a substituted or unsubstituted C₁-C₃₀ alkyl group, a substituted or unsubstituted C₁-C₃₀ alkoxy group, a substituted or unsubstituted C₆-C₃₀ aryl group, a substituted or unsubstituted C₆-C₃₀ arylalkyl group, a substituted or unsubstituted C₆-C₃₀ aryloxy group, a substituted or unsubstituted C₂-C₃₀ heteroaryl group, a substituted or unsubstituted C₂-C₃₀ heteroarylalkyl group, a substituted or unsubstituted C₂-C₃₀ heteroaryloxy group, a substituted or unsubstituted C₅-C₃₀ cycloalkyl group, a substituted or unsubstituted C₅-C₃₀ heterocycloalkyl group, a substituted or unsubstituted C₁-C₃₀ alkylester group, and a substituted or unsubstituted C₆-C₃₀ arylester group;
R₄ is formed of a conjugated conducting polymer chain; and
X and X′ are each independently selected from the group consisting of a simple bond, O, S, a substituted or unsubstituted C₁-C₃₀ alkylene group, a substituted or unsubstituted C₁-C₃₀ heteroalkylene group, a substituted or unsubstituted C₆-C₃₀ arylene group, a substituted or unsubstituted C₆-C₃₀ arylalkylene group, a substituted or unsubstituted C₂-C₃₀ heteroarylene group, a substituted or unsubstituted C₂-C₃₀ heteroarylakylene group, a substituted or unsubstituted C₅-C₂₀ cycloalkylene group, a substituted or unsubstituted C₅-C₃₀ heterocycloalkylene group, and a substituted or unsubstituted C₆-C₃₀ arylester group.

15. The OLED of claim 14, wherein the ionic group comprises an anionic group selected from the group consisting of PO₃²⁻, SO₃^{-, COO}⁻, I⁻, CH₃COO⁻, and a cationic group including a metal ion selected from the group consisting of Na⁺, K⁺, Li⁺, Mg⁺², Zn⁺², and Al⁺³ and an organic ion selected from the group consisting of H⁺, NH₄⁺, and CH₃(—CH₂—)ₙO⁺ where n is an integer from 0 through 50, and the anionic group is in pair with the cationic group.

16. The OLED of claim 14, wherein at least one of R₁, R₂, R₃, R′₁, R′₂, R′₃, and R′₄ in the self-doped conducting polymer is fluorine or a group substituted with fluorine.

17. The OLED of claim 1, wherein the fluorinated ionomer includes a polymer having at least one of the repeating units represented by Formulas 2 through 12: 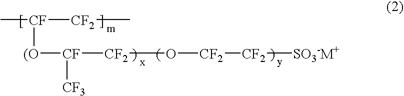
where m is an integer from 1 to 10,000,000, and x and y are each a number from 0 to 10, M⁺ is Na⁺, K⁺, Li⁺, H⁺, CH₃(CH₂)ₙNH₃⁺ (n is an integer from 0 to 50), NH₄⁺, NH₂⁺, NHSO₂CF₃⁺, CHO⁺, C₂H₅OH⁺, CH₃OH⁺, and RCHO⁺where R is an alkyl group, that is, CH₃(CH₂)ₙ⁻ where n is an integer from 0 to 50; 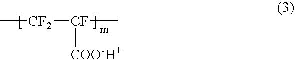
where m is an integer from 1 to 10,000,000; 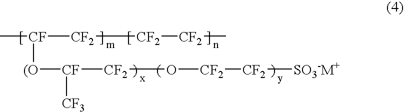
where 0<m≦10,000,000, 0≦n<10,000,000, and x and y are each a number from 0 to 20, M⁺ is Na⁺, K⁺, Li⁺, H⁺, CH₃(CH₂)ₙNH₃⁺ (n is an integer from 0 to 50), NH₄⁺, NH₂⁺, NHSO₂CF₃⁺, CHO⁺, C₂H₅OH⁺, CH₃OH⁺, and RCHO⁺ where R is an alkyl group, that is, CH₃(CH₂)ₙ⁻ where n is an integer from 0 to 50; 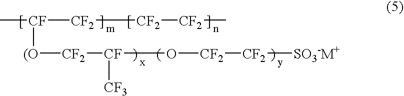
where 0<m≦10,000,000, 0≦n<10,000,000, and x and y are each 0 to 20, M⁺ is Na⁺, K⁺, Li⁺, H⁺, CH₃(CH₂)ₙNH₃⁺ (n is an integer from 0 to 50), NH₄⁺, NH₂⁺, NHSO₂CF₃⁺, CHO⁺, C₂H₅OH⁺, CH₃OH⁺, and RCHO⁺ where R is an alkyl group, that is, CH₃(CH₂)ₙ⁻ where n is an integer from 0 to 50; 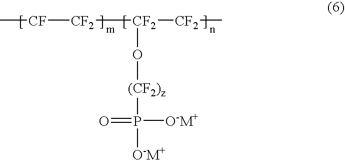
where 0<m≦10,000,000, 0≦n<10,000,000, and x and y are each a number from 0 to 20, M⁺ is Na⁺, K⁺, Li⁺, H⁺, CH₃(CH₂)ₙNH₃⁺ (n is an integer from 0 to 50), NH₄⁺, NH₂⁺, NHSO₂CF₃⁺, CHO⁺, C₂H₅OH⁺, CH₃OH⁺, and RCHO⁺ where R is an alkyl group, that is, CH₃(CH₂)ₙ⁻ where n is an integer from 0 to 50; 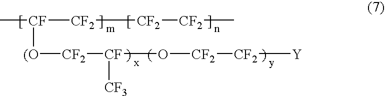
where 0<m≦10,000,000, 0≦n<10,000,000, and x and y are each a number from 0 to 20, M⁺ is Na⁺, K⁺, Li⁺, H⁺, CH₃(CH₂)ₙNH₃⁺ (n is an integer from 0 to 50), NH₄⁺, NH₂⁺, NHSO₂CF₃⁺, CHO⁺, C₂H₅OH⁺, CH₃OH⁺, and RCHO⁺ where R is an alkyl group, that is, CH₃(CH₂)ₙ⁻ where n is an integer from 0 to 50; 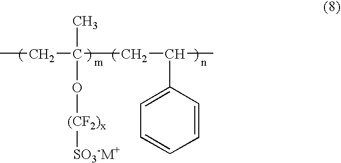
where 0<m≦10,000,000, 0≦n<10,000,000, and x and y are each a number from 0 to 20, M⁺ is Na⁺, K⁺, Li⁺, H⁺, CH₃(CH₂)ₙNH₃⁺ (n is an integer from 0 to 50), NH₄⁺, NH₂⁺, NHSO₂CF₃⁺, CHO⁺, C₂H₅OH⁺, CH₃OH⁺, and RCHO⁺ where R is an alkyl group, that is, CH₃(CH₂)ₙ⁻ where n is an integer from 0 to 50; 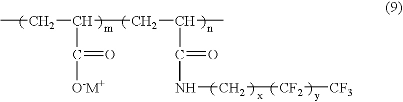
where 0<m≦10,000,000, 0≦n<10,000,000, and x and y are each a number from 0 to 20, M⁺ is Na⁺, K⁺, Li⁺, H⁺, CH₃(CH₂)ₙNH₃⁺ (n is an integer from 0 to 50), NH₄⁺, NH₂⁺, NHSO₂CF₃⁺, CHO⁺, C₂H₅OH⁺, CH₃OH⁺, and RCHO⁺ where R is an alkyl group, that is, CH₃(CH₂)ₙ⁻ where n is an integer from 0 to 50; 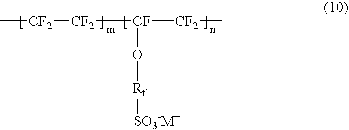
where 0≦m<10,000,000, 0<n≦10,000,000, R_{f}═—(CF₂)_{z}— (z is an integer from 1 to 50, except 2), —(CF₂CF₂O)_{z}CF₂CF₂— (z is an integer from 1 to 50), —(CF₂CF₂CF₂O)_{z}CF₂CF₂— (z is an integer from 1 to 50), M⁺ is Na⁺, K⁺, Li⁺, H⁺, CH₃(CH₂)ₙNH₃⁺ (n is an integer from 0 to 50), NH₄⁺, NH₂⁺, NHSO₂CF₃⁺, CHO⁺, C₂H₅OH⁺, CH₃OH⁺, and RCHO⁺ where R is an alkyl group, that is, CH₃(CH₂)ₙ⁻ where n is an integer from 0 to 50; 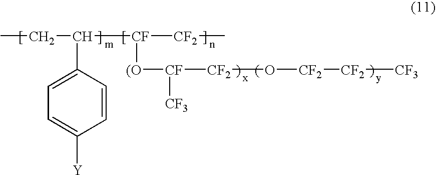
where m and n 0≦m<10,000,000, 0<n≦10,000,000, x and y are each a number from 0 to 20, Y is one selected from the group consisting of —SO₃⁻M⁺, —COO⁻M⁺, —SO₃⁻NHSO₂CF3⁺, and —PO₃²⁻(M⁺)₂, M⁺ is Na⁺, K⁺, Li⁺, H⁺, CH₃(CH₂)ₙNH₃⁺ (n is an integer from 0 to 50), NH₄⁺, NH₂⁺, NHSO₂CF₃⁺, CHO⁺, C₂H₅OH⁺, CH₃OH⁺, and RCHO⁺ where R is an alkyl group, that is, CH₃(CH₂)ₙ⁻ where n is an integer from 0 to 50; and 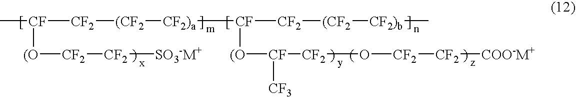
where 0≦m<10,000,000, 0<n≦10,000,000, M⁺ is Na⁺, K⁺, Li⁺, H⁺, CH₃(CH₂)ₙNH₃⁺ (n is an integer from 0 to 50), NH₄⁺, NH₂⁺, NHSO₂CF₃⁺, CHO⁺, C₂H₅OH⁺, CH₃OH⁺, and RCHO⁺ where R is a C₁-C₅₁ alkyl group, that is, CH₃(CH₂)ₙ⁻ where n is an integer from 0 to 50.

18. The OLED of claim 3, further comprising a third ionomer having a different structure than the conducting polymer and the fluorinated ionomer.

19. The OLED of claim 18, wherein the third ionomer includes an ionic group of a polymer acid.

20. The OLED of claim 3, wherein the conducting polymer is polystyrenesulfonic acid-graft-polyanyline.

21. The OLED of claim 3, wherein the perfluorinated ionomer is represented by Formula 14: 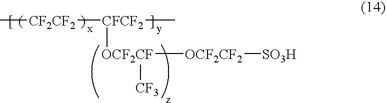
(where x=1300, y=200, x=1.

22. The OLED of claim 2, wherein the solution process includes at least one coating process selected from spin coating, dip coating, spray printing, ink-jet printing, and nozzle printing, drying, and heat treatment.

23. The OLED of claim 7, further comprising a hole blocking layer between the emitting layer and the electron transporting layer.

24. An organic light emitting device (OLED), comprising:
a first electrode;
a second electrode;
an emitting layer between the first electrode and the second electrode;
a hole injection layer between the first electrode and the emitting layer, the hole injection layer formed on the first electrode through a solution process, the hole injection layer formed of a composition comprising a conducting polymer and at least one of a fluorinated ionomer and a perfluorinated ionomer; and
a hole transporting layer between the hole injection layer and the emitting layer, the absolute value of the work function, the IP or the highest occupied molecular orbital (HOMO) level of the hole injection layer being greater than or equal to the absolute value of the HOMO level of the hole transporting layer.
